(19) United States
(12) Patent Application Publication
(10) Pub. No.: US 2017/0250379 A1
(43) Pub. Date: Aug. 31, 2017

(54) EVAPORATION SOURCE HAVING MULTIPLE SOURCE EJECTION DIRECTIONS

(71) Applicant: APPLIED MATERIALS, INC., Santa Clara, CA (US)

(72) Inventor: Donald VERPLANCKEN, Houston, TX (US)

(21) Appl. No.: 15/361,882

(22) Filed: Nov. 28, 2016

(51) Int. Cl. H01L 51/56; H01L 51/00; C23C 14/24

(52) U.S. Cl. CPC H01L 51/56; C23C 14/24; H01L 51/001; H01L 51/0011

(57) ABSTRACT

A deposition source assembly for evaporating source material an apparatus including a deposition source assembly and a method of evaporating source materials with a deposition source assembly are described. The deposition source assembly includes a body including a source material reservoir and a distribution pipe assembly for guiding gaseous source material in a first direction and a second direction opposite to the first direction.

### TECHNICAL FIELD

Embodiments of the present disclosure relate to deposition of source material on two facing substrates, particularly deposition of source material on two facing substrates with a scanning source, i.e. a moving source. Embodiments of the present disclosure particularly relate to a deposition source assembly for evaporating source material, a deposition apparatus for depositing evaporated source material on a substrate, and a method of depositing evaporated source material on two or more substrates.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc. for displaying information. OLEDs can also be used for general space illumination. The range of colors, brightness, and viewing angle possible with OLED displays is greater than that of traditional LCD displays because OLED pixels directly emit light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are all deposited on a substrate in a manner to form a matrix display panel having individually energizable pixels.

Deposition throughput, and deposition system size, and, thus, footprint, to form film layers onto a substrate can be enhanced by using the same source to deposit the film layer on different substrates in the same chamber. Such systems may use a scanning evaporation source which scans across a first substrate to deposit a film layer thereon, and then rotates 180 degrees and scans across a second substrate in the chamber to form a thin-film, e.g a layer, on the substrate. The difficulty in controlling the source position in the chamber, and the mechanisms for scanning movement thereof, are further complicated by the need to rotate the source.

In view of the above, it is beneficial to provide an improved evaporation source assembly, an improved deposition apparatus or an improved processing system including an improved deposition apparatus, respectively, and an improved method of depositing evaporated source material on two or more substrates.

### SUMMARY

According to one embodiment, a deposition source assembly for evaporating source material is provided. The deposition source assembly includes a body including a source material reservoir and a distribution pipe assembly for guiding gaseous source material in a first direction and a second direction opposite to the first direction.

According to another embodiment, a deposition apparatus for depositing evaporated source material on a substrate is provided. The apparatus includes a vacuum chamber; a first substrate support track provided in the vacuum chamber, wherein the first substrate support track is configured to support a substrate in a first deposition area; a second substrate support track provided in the vacuum chamber, wherein the second substrate support track is configured to support a further substrate in a second deposition area, and wherein a space is provided between the first deposition area and the second deposition area; and a deposition source assembly for evaporating source material provided in the space between the first deposition area and the second deposition area, wherein the deposition source assembly comprises a body including a source material reservoir and a distribution pipe assembly for ejecting gaseous source material on a first side in a first direction and on a second side opposite to the first side in a second direction.

According to a further embodiment, a method of depositing evaporated source material on two or more substrates is provided. The method includes moving a first substrate of the two or more substrates in a vacuum process chamber along a first substrate support track; moving the first substrate and a deposition source assembly relative to each other while ejecting gaseous source material at a first side of the deposition source assembly; moving a second substrate of the two or more substrates in the vacuum process chamber along a second substrate support track; and moving the second substrate and the deposition source assembly relative to each other while ejecting gaseous source material at a second side of the deposition source assembly opposite to the first side of the deposition source assembly.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1A shows a schematic view of a process module illustrating embodiments of the present disclosure;

FIG. 1B shows a schematic view of an exemplary deposition source assembly illustrating embodiments of the present disclosure;

FIG. 2 shows a schematic view of a further process module illustrating embodiments of the present disclosure and having a deposition source assembly for co-evaporation of three materials;

FIG. 3A shows a schematic view of two neighboring routing modules each having a process module connected thereto according to embodiments described herein;

FIG. 3B shows a schematic perspective view of a routing module of a processing system according to embodiments described herein;

FIG. 4A shows a schematic view of a further process module illustrating embodiments of the present disclosure and having a deposition source assembly with distribution pipes provided back to back;

FIG. 4B shows a schematic view of an exemplary deposition source assembly illustrating embodiments of the present disclosure as shown in FIG. 4A;

FIG. 5A shows a schematic view of a further process module illustrating embodiments of the present disclosure and having a deposition source assembly with distribution pipes provided back to back;

FIG. 5B shows a schematic view of a further process module illustrating embodiments of the present disclosure and having a deposition source assembly with distribution pipes provided side by side;

FIG. 6A shows a schematic view of a processing system having a first modular layout configuration according to embodiments described herein;

FIG. 6B shows a schematic view of a portion of a processing system having a second modular layout configuration according to embodiments described herein;

FIG. 7A shows a schematic view of a further process module illustrating embodiments of the present disclosure and having a deposition source assembly for co-evaporating three materials, wherein a moving source is provided;

FIG. 7B shows a schematic view of a further process module illustrating embodiments of the present disclosure and having a deposition source assembly for co-evaporating three materials, wherein moving substrates are provided;

FIG. 8 shows a schematic view of a further process module illustrating embodiments of the present disclosure and having a deposition source assembly for co-evaporating three materials, wherein a moving source is provided;

FIGS. 9A and 9B show schematic views of a transportation apparatus for transporting a deposition source in a processing system according to embodiments described herein;

FIG. 9C shows a schematic view of a deposition source support for supporting a deposition source according to embodiments described herein;

FIGS. 10A and 10B show schematic views of various embodiments of a further transportation apparatus for transporting a carrier assembly in a processing system according to embodiments described herein; and

FIG. 11 shows a flowchart illustrating embodiments of the present disclosure and relating to methods to deposit evaporated source material.

### DETAILED DESCRIPTION OF EMBODIMENTS

Reference will now be made in detail to the various embodiments, one or more examples of which are illustrated in the figures. Within the following description of the drawings, the same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Embodiments described herein particularly relate to deposition of organic materials, e.g. for OLED display manufacturing, e.g. on large area substrates. According to some embodiments, large area substrates or carriers supporting one or more substrates, i.e. large area carriers, may have a size of at least 0.174 m². Typically, the size of the carrier can be about 1.4 m² to about 8 m², more typically about 2 m² to about 9 m² or even up to 12 m². Typically, the rectangular area in which the substrates are supported are carriers having sizes for large area substrates as described herein. For instance, a large area carrier, which would correspond to an area of a single large area substrate, can be GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. Half sizes of the GEN generations may also be provided for OLED display manufacturing.

According to typical embodiments, which can be combined with other embodiments described herein, the substrate thickness can be from 0.1 to 1.8 mm and the embodiments described herein can be adapted for such substrate thicknesses. However, particularly the substrate thickness can be about 0.9 mm or below, such as 0.5 mm or 0.3 mm, and the embodiments described are adapted for such substrate thicknesses.

The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

According to embodiments described herein, the substrate may be made of any material suitable for material deposition. For instance, the substrate may be made of a material selected from the group consisting of glass (for instance soda-lime glass, borosilicate glass etc.), metal, polymer, ceramic, compound materials, carbon fiber materials or any other material or combination of materials which can be coated by a deposition process.

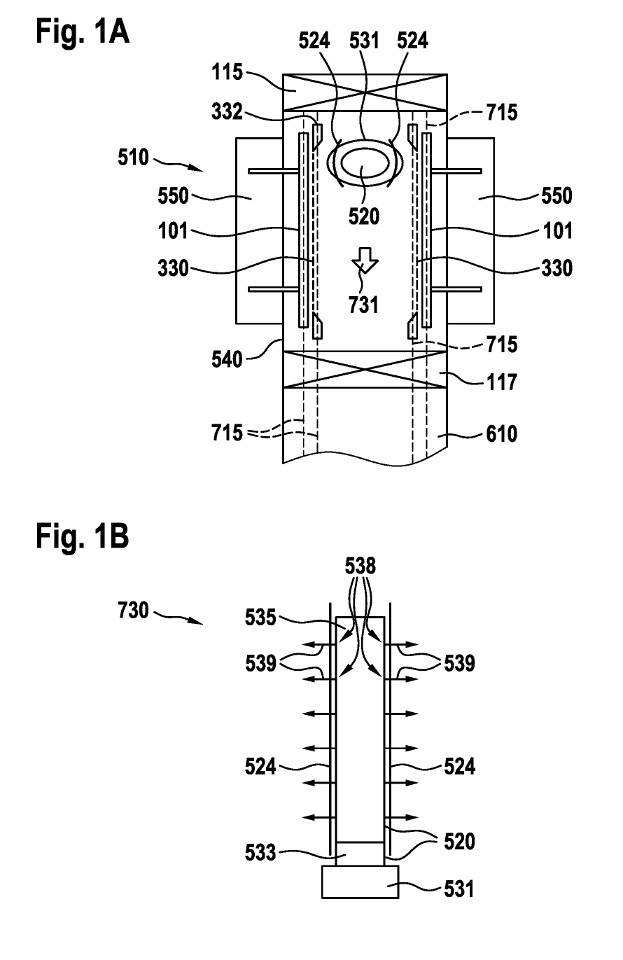

FIG. 1A shows a process module 510. The process module 510 includes a vacuum process chamber 540. The vacuum process chamber 540 is connected to a gate valve 115, wherein during operation substrate 101 and/or mask 330 with mask carriers 332 can be moved into and out of the vacuum process chamber 540 through gate valve 115. The gate valve 115 can be connected to a further vacuum chamber, such as a routing module. By opening and closing the gate valve 115, the vacuum process chamber 540 can be vacuum sealed or open, respectively, with respect to the further vacuum chamber.

The process module 510 may further include, as shown in FIG. 1A, a service module 610. The service module 610 can be connected to the vacuum process chamber 540 via a further gate valve 117. Accordingly, the service module 610, which provides another vacuum chamber, can be vacuum sealed from the vacuum process chamber 540 by closing the further gate valve 117. For example, the further gate valve 117 may be opened to move the deposition source assembly 730 (see FIG. 1B) from the vacuum process chamber 540 to the service module 610 or vice versa.

A deposition source assembly 730 can be serviced or maintained in the service module 610. For example, the deposition source assembly 730 may be refilled with new source material or other maintenance steps may be conducted. Annually serviced deposition source assembly 730 can be introduced from the service module 610 into the vacuum process chamber 540 of the process module 510 through further gate valve 117, for example while gate valve 117 is in an open position. Thereafter, the further gate valve 117 can be closed for operation of the process module 510, i.e. for deposition of source material on a substrate 101.

According to embodiments described herein, a deposition source assembly 730 is provided for depositing source material on a substrate. The deposition source assembly 730 can be an evaporation source, particularly an evaporation source for depositing one or more organic materials on a substrate to form a layer of an OLED device. The deposition source assembly 730 includes a source support 531. The source support 531 supports the elements of the deposition source assembly 730 and can provide, for example, a moving mechanism for the deposition source assembly 730 to provide for a scanning source capable of depositing a film layer on two facing substrates, particularly without the need to rotate the source.

The deposition source assembly 730 includes a crucible 533 or the source material reservoir. The crucible or source material reservoir is heated to vaporize the source material into a gas by at least one of evaporation and sublimation of the source material. The deposition source assembly 730 includes a heater to vaporize the source material in the crucible 533, i.e. the source material reservoir, into the gaseous source material. The deposition source assembly 730 includes a body or a deposition source 520 including the crucible 533 and a distribution pipe 535. The distribution pipe 535 may guide the gas of source material from the crucible 533 to two or more openings in the distribution pipe 535.

According to some embodiments described herein, which can be combined with other embodiments described herein, the body of the deposition source assembly, i.e. the deposition source 520, includes a source material reservoir or crucible 533 and a distribution pipe assembly, including for example the distribution pipe 535. The distribution pipe assembly is configured for guiding gaseous source material in a first direction and the second direction opposite to the first direction. This is exemplarily indicated in FIG. 1B by arrows 539. The gaseous source material, for example a material for depositing a thin film of an OLED device, is guided within the distribution pipe 535 and exits the distribution pipe 535 through one or more openings 538.

It has been found that even though one or more openings may be provided on both sides of a distribution pipe, i.e. the number of openings are doubled, stable vapor deposition is still possible, i.e. a pressure inside the distribution pipe can be sufficiently higher than outside the distribution pipe, for example in the surrounding vacuum of the vacuum process chamber. For example, the pressure inside the distribution pipe can be at least one order of magnitude higher than outside the distribution pipe, e.g. in the vacuum process chamber.

According to some embodiments, which can be combined with other embodiments described herein, the source material can be an organic material deposited on the substrate for manufacturing of an OLED device. The source material can be vaporized to form a gaseous source material by evaporation or sublimation. It is to be understood that sublimation may be utilized for some materials and, depending on the material, the term “evaporation” used herein is to be understood as including the option of sublimation.

As shown in FIGS. 1A and 1B, one or more movable shutters 524 can be provided. The one or more movable shutters 524 can be provided to block gaseous source material exiting from the openings 538. According to some embodiments, which can be combined with other embodiments described herein, the one or more movable shutters can be configured and/or utilized for selectively blocking the gaseous source material to propagate at least a first direction or an opposing second direction. That is the propagation of the gaseous source material to along at least a first direction or an opposing second direction is blocked. For example, the first direction can be the left-hand side in FIGS. 1A and 1B and the second direction, which is opposite to the first direction, can be the right-hand side in FIGS. 1A and 1B.

According to typical embodiments, the first direction in which a portion of the gaseous source material is guided and the second direction, which is opposite to the first direction, in which a further portion of the gaseous source material is guided may be opposite in the sense that an angle between the first direction the second direction is 180°. However, according to embodiments described herein, which can be combined with other embodiments described herein, the angle between the first direction and the second direction may also deviate from 180°, i.e. an angle of 120° to 180° between the first direction and the second direction is considered to refer to opposite directions in the sense that for example the first direction has a main direction of an evaporation plume which points towards an area on one side of the deposition source assembly and the second direction has a main direction of an evaporation plume which points to an area on an opposite side of the deposition source assembly.

As shown in FIG. 1A, a first substrate 101 is provided on e.g. the left side of the deposition source assembly and second substrate 101 is provided on an opposite side of the deposition source assembly. Accordingly, gaseous source material propagating towards the substrate on the left-hand side is deposited on the first substrate 101 and gaseous source material propagating towards the substrate on the right-hand side is deposited on the second substrate 101. Typically, these propagation directions can be opposite directions, i.e. the main directions of the evaporation plumes are opposite directions. According to some embodiments, directing material to the left-hand side and to the right-hand side does not require an angle of 180° between the first direction and the second direction but slightly smaller angles may also be appropriate.

As indicated by arrow 731 in FIG. 1A, the deposition source 520 can be moved from the upper position shown in FIG. 1A to a lower position in FIG. 1A. Due to such a movement, the deposition source 520 scans along one dimension of the substrate 101 for deposition of the thin-film of the gaseous source material. During scanning of the deposition source 520 along one of the substrate 101, one of the movable shutters 524 can be operated to be in an open position such that the gaseous source material can propagate toward the substrate. Thereafter, during a further scanning, for example scanning in the direction opposite to arrow 731, the first one of the movable shutters can be closed. The other one of the movable shutters 524 can be operated to be open position such that the gaseous source material can propagate toward the other substrate of the substrates 101.

For deposition of a layer of source materials, e.g. organic material, on e.g. the left substrate in FIG. 1A, the first movable shutter on the left side is in an open position. After e.g. the left substrate 101 in FIG. 1A has been deposited with the layer of organic material, the first movable shutter 524 is operated to be in a closed position and the second movable shutter 524, for example the shutter controlling the propagation in the second opposite direction, is operated to be in an open position. During deposition of the organic material on the first substrate (the substrate on the left-hand side in FIG. 1A), the second substrate has been positioned and aligned with respect to the mask 330. According to some embodiments, which can be combined with other embodiments described herein, the alignment of the substrate relative to the mask 330 can be provided by an alignment system 550. Accordingly, after the selection of the deposition direction by operating the one or more movable shutters 524, the substrate on the right-hand side, i.e. the second substrate 101, can be coated with a layer of organic material. While the second substrate 101 is coated with the organic material, the first substrate can be moved out of the vacuum processing chamber 540. In light of the above, a scanning source, i.e. deposition source 520 or deposition source assembly 730, respectively, capable of depositing a film layer on two facing substrates 101, without the need to rotate the source, is provided.

According to some embodiments, a first movable shutter of one or more movable shutters can be configured to be able to block gaseous source material in a first direction, for example the left direction in FIG. 1A, and a second movable shutter of the one or more movable shutters can be configured to be able to block gaseous source material guided in the second direction, for example the right direction in FIG. 1A. According to yet further embodiments, which can be combined with other embodiments described herein, one shutter can be provided to selectively open and close openings 538 on opposing sides of the distribution pipe 535. Yet further, the one or more shutters can be configured to be able to block gaseous source material guided in both the first and the second direction. This may for example be beneficial during maintenance or servicing of the source or during time periods in which no substrate is provided in the vacuum process chamber 540.

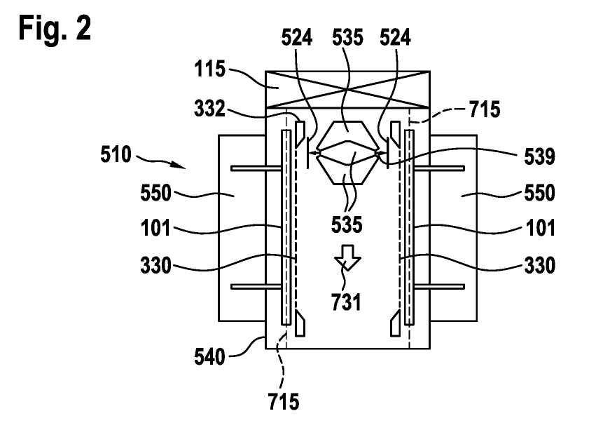

FIG. 2 illustrates a yet further embodiment of a process module 510. For the fabrication of OLED stacks with high efficiency, the co-deposition or co-evaporation of two or more materials, for example host and dopant, leading to OLED layers is beneficial. Further, it has to be considered that there are several process conditions for the evaporation of the source materials. Particularly organic materials can be sensitive such that different evaporation temperatures may be beneficial for different organic materials that are guided toward the substrate to form one thin film.

Accordingly, FIG. 2 shows a process module 510 with a vacuum process chamber 540. A deposition source assembly 730 is moved within the vacuum process chamber 540, for example along arrow 731, and may be moved backward after the first movement in a direction opposite to arrow 731. The deposition source assembly includes three distribution pipes 535. For example, each distribution pipe 535 can be in fluid communication with an independent source material reservoir or crucible 533. Accordingly the deposition source assembly may also include three source material reservoirs. The three distribution pipes 535 can be supported by a source support 531. As described in more detail below, the source support 531 can provide for a movement of the scanning source. It is particularly beneficial if the movement of the scanning source is provided with a contactless movement i.e. a movement including magnetic levitation such that particle generation can be reduced or even avoided.

According to yet further embodiments, which can be combined with other embodiments described herein, one or more openings on a first side of a first distribution pipe of neighboring distribution pipes and one or more openings on a first side of a second distribution pipe of neighboring distribution pipes can have a distance along a first dimension smaller than 50% of the width of the distribution pipe along the same first dimension. Even more, the distance can, according to some embodiments, be 20% or smaller.

According to some embodiments, which can be combined with other embodiments described herein, the distribution pipe assembly can include one or more distribution pipes. The distribution pipe assembly can include a first plurality of openings forming a line source for guiding the gaseous source material in the first direction and second plurality of openings forming a further line source for guiding the gaseous source material in the second direction, which is opposite (120° to 180°) to the first direction. As shown in FIGS. 1A and 2, the first plurality of openings and the second plurality of openings can be provided in one distribution pipe forming a line source for one gaseous source material. As exemplarily shown in FIG. 2, two or more of distribution pipes forming two line sources can be included in one deposition source assembly.

FIGS. 1A and 2 show exemplary deposition apparatuses for depositing evaporated source material on a substrate in the form of, for example, process modules 510. A process module according to embodiments described herein includes a vacuum process chamber 540 and a transportation track arrangement 715. FIG. 1A has a transportation track arrangement 715 with four transportation tracks. Two transportation tracks are provided for substrates 101, one on each side of the deposition source assembly. Two further transportation tracks are provided for the mask carriers 332 carrying the mask 330. The two further transportation tracks are also provided on opposite sides of the deposition source assembly. Masks 330 on mask carrier 332 and substrates 101, typically on substrate carriers, can be moved into and out of the vacuum process chamber 540 along the respective transportation tracks of the transportation track arrangement 715.

An alternative arrangement of the transportation track arrangement 715, which can be combined with other embodiments described herein, is exemplarily shown in FIG. 2. The transportation track arrangement 715 shown in FIG. 2 includes a first transportation track and a second transportation track. For example, the first transportation track and the second transportation track can be a first substrate support track provided in the vacuum chamber and the second substrate support track provided in the vacuum chamber. The first substrate support track is configured to support the substrate in a first deposition area and the second substrate support track is configured to support a substrate in a second deposition area.

A mask or mask carrier, respectively, and a substrate or substrate carrier, respectively, can be moved along the first transportation track or the second transportation track, respectively. In order to provide the mask between the deposition source 520 and the substrate, the movement in a direction, for example perpendicular to a substrate movement along a transportation track, can be provided for the mask carrier.

The deposition apparatuses for depositing evaporated source material as exemplarily shown in FIGS. 1A and 2 include a deposition source assembly for evaporating source material as for example shown in FIG. 1B, wherein the deposition source assembly comprises a body including a source material reservoir and a distribution pipe assembly for guiding gaseous source material in a first direction and the second direction opposite to the first direction. According to some embodiments, which can be combined with other embodiments described herein, the distribution pipe assembly can have a distribution pipe with a first opening directing gaseous source material in one direction and a second opening directing gaseous source material in an opposite direction. According to yet further embodiments, which can be combined with other embodiments described herein, the distribution pipe assembly can have a distribution pipe with a first plurality of openings forming a first line source and a second plurality of openings forming a second line source. The first line source can eject gaseous source material in a first direction and the second line source can eject gaseous source material in a second direction, which is opposite to the first direction.

A first opening and the second opening can be opened and closed by one or more shutters for selectively blocking the gaseous source material. The first plurality of openings of the first line source and the second plurality of openings of the second line source can be opened and closed by one or more shutters for selectively blocking the gaseous source material. Accordingly, a deposition source assembly 730 according to embodiments described herein can eject source material in two, for example opposite directions. Embodiments described herein are beneficially able to deposit thin films on substrates facing each other, wherein deposition can for example take place alternatingly.

According to some embodiments, which can be combined with other embodiments described herein, a substrate in a first deposition area, a substrate in the second deposition area and the length of the distribution pipe, for example the length of the line source, may be essentially parallel to a direction of gravity. Essentially parallel is to be understood as having an angle of −20° to 20°, such as −15° to 15°. According to these embodiments, the substrates are essentially vertically oriented (essentially −20°<substrate orientation<+20° deviating from vertical). Accordingly, FIGS. 1A and 2 can be considered a top view whereas FIG. 1B would be a side view. According to other embodiments, which can be combined with other embodiments described herein, a substrate in the first deposition area, a substrate in the second deposition area and the length of the distribution pipe, for example the length of the line source, may be essentially horizontal. Essentially horizontal also include angles with an absolute value of 20° or smaller, such as 15° or smaller. Accordingly, FIGS. 1A and 2 can be considered side views and FIG. 1B would be a top view.

Embodiments described herein provide a deposition source assembly with a body or deposition source having a source material reservoir, and a heater to vaporize the source material into a gas, by at least one of evaporation and sublimation of the source material. The body can extend horizontally and gaseous source material exit(s), e.g. openings, are included on opposed sides of the body. In operation, the source exit(s) on only one side the source are exposed to the gaseous source material as the source and substrate move relative to one another. According to some embodiments, at least one shutter is provided in the source to selectively direct the gaseous source material to exit(s) on only one side of the source, or to block the gaseous material from the exits on one or both sides of the source.

FIGS. 1A and 2 exemplarily show deposition apparatuses for depositing evaporated source material on a substrate in the form of for example process modules 510. Two alternatives are provided, both of which may be combined with other embodiments. The process module 510 of FIG. 1A is connected to a service module 610. This enables to move a deposition source assembly from the vacuum process chamber 540 directly to the service module 610. The process module 510 of FIG. 2 does not have a service module 610 which is directly adjacent to the vacuum process chamber 540. This provides the benefit of reduced footprint of a processing system. Yet, in order to serve as a deposition source assembly 730, the deposition source assembly needs to travel through gate valve 115 to one or more neighboring vacuum chambers to be moved to a maintenance or service area.

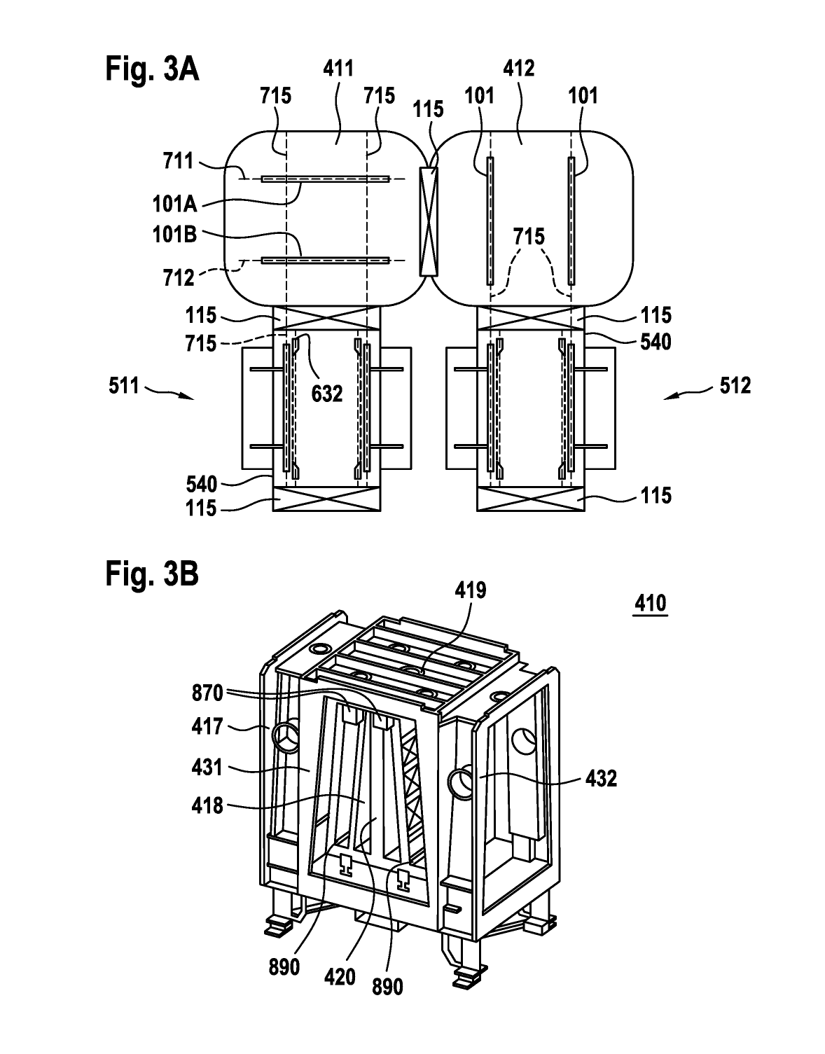

In FIG. 3A, a portion of a processing system is shown in which two process modules are connected to each other via two adjacent routing modules. In particular, FIG. 3A shows a portion of a processing system in which a first routing module 411 is connected to a first process module 511 and to a further routing module 412. The further routing module 412 is connected to a further process module 512. As shown in FIG. 3A, a gate valve 115 can be provided between neighboring routing modules. The gate valve 115 can be closed or opened to provide a vacuum seal between the routing modules. The existence of a gate valve may depend on the application of the processing system, e.g. on the kind, number, and/or sequence of layers of organic material deposited on a substrate. Accordingly, one or more gate valves can be provided between transfer chambers or routing modules. Alternatively, no gate valve is provided between any of the transfer chambers or routing modules.

As described with reference to FIG. 3B, according to some embodiments which can be combined with other embodiments described herein, one or more of the routing modules may include a vacuum routing chamber 417 provided with a rotation unit 420. Therein, the substrate provided in a substrate carrier and/or the mask provided in a mask carrier employed during operation of the processing system can be rotated around a rotation axis, e.g. a vertical central axis. According to some embodiments, which can be combined with other embodiments described herein, a routing module or transfer chamber as described herein can be configured for receiving substrates in an essentially vertical orientation and for transferring substrates in a further chamber in an essentially vertical orientation.

Typically, the rotation unit 420 is configured for a rotating transportation track arrangement 715 including the first transportation track 711 and the second transportation track 712, as exemplarily shown in FIG. 3A. Accordingly, the orientation of the transportation track arrangement 715 inside the routing module can be varied. In particular, the routing module may be configured such that the first transportation track 711 and the second transportation track 712 can be rotated by at least 90°, for example by 90°, 180° or 360°, such that the carriers on the tracks are rotated in the position to be transferred in one of the adjacent chambers of the processing system.

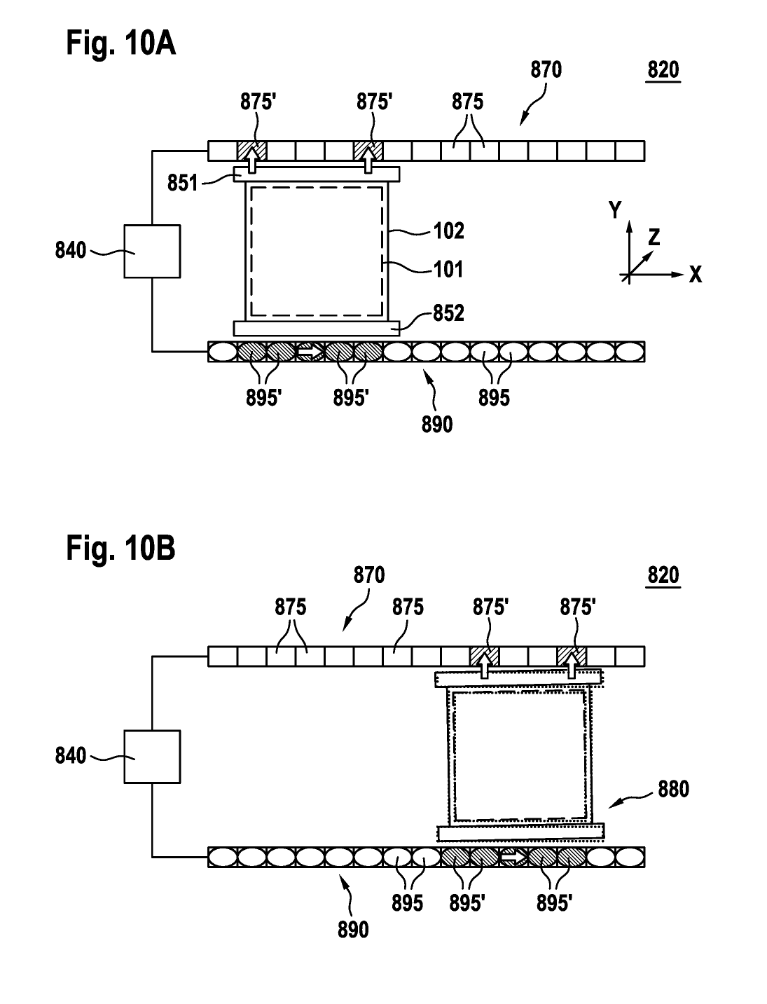

According to typical embodiments, the first transportation track 711 and the second transportation track 712 are configured for contactless transportation of the substrate carrier and the mask carrier. In particular, the first transportation track 711 and the second transportation track 712 may include a further guiding structure 870 and a drive structure 890 configured for a contactless translation of the substrate carrier and the mask carrier, as described in more detail with reference to FIGS. 10A-10B.

As illustrated in FIG. 3A, in the first routing module 411, two substrates, e.g. a first substrate 101A and a second substrate 101B, are rotated. The two transportation tracks, e.g. the first transportation track 711 and the second transportation track 712, on which the substrates are located, are rotated with respect to the two transportation tracks. Accordingly, two substrates on the transportation tracks are provided in a position to be transferred to an adjacent further routing module 412.

As exemplarily shown in FIG. 3A, according to some embodiments, which can be combined with other embodiments described herein, the transportation tracks of transportation track arrangement 715 may extend from the vacuum process chamber 540 into a vacuum routing chamber 417. Accordingly, one or more of the substrates 101 can be transferred from a vacuum process chamber to an adjacent vacuum routing chamber. Further, as exemplarily shown in FIG. 3A, a gate valve 115 may be provided between a process module and a routing module which can be opened for transportation of the one or more substrates. As exemplarily shown in FIG. 3A, also the further process module 512 can be connected to the further routing module 412 by a gate valve 115. Accordingly, it is to be understood that a substrate can be transferred from the first process module to the first routing module, from the first routing module to the further routing module, and from the further routing module to a further process module. Accordingly, several processes, e.g. depositions of various layers of organic material on a substrate can be conducted without exposing the substrate to an undesired environment, such as an atmospheric environment or non-vacuum environment.

As described above, according to some embodiments, which can be combined with other embodiments described herein, the processing system may be configured such that a substrate can be moved out of a process module along a first direction. In that way, the substrate is moved along an essentially straight path into an adjacent vacuum chamber, for example, a vacuum routing chamber which may also be referred to as vacuum transfer chamber herein. In the transfer chamber, the substrate can be rotated such that the substrate can be moved along a second straight path in a second direction different from the first direction. As exemplarily shown in FIG. 3A, the second direction can be substantially perpendicular to the first direction. For transferring the substrate to the further process module 512, the substrate can be moved from the first routing module 411 into the further routing module 412 in the second direction and can then be rotated in the further routing module 412, e.g. by 180°. Thereafter, the substrate can be moved into the further process module 512.

As exemplarily shown in FIG. 3B, typically the routing module 410 includes a rotation unit 420 which is configured to rotate the substrate carrier and/or the mask carrier such that the substrate carrier and/or the mask carrier can be transferred to a neighboring connected process module. In particular, the rotation unit 420 may be provided in a vacuum routing chamber 417, particularly a vacuum routing chamber which can be configured to provide vacuum conditions as described herein. More specifically, the rotation unit may include a rotation drive configured for rotating a support structure 418 for supporting a substrate carrier and/or a mask carrier around a rotation axis 419, as exemplarily shown in FIG. 3B. In particular, the rotation drive may be configured for providing a rotation of at least 180° of the rotation unit in a clockwise and an anti-clockwise direction.

Further, as exemplarily shown in FIG. 3B, the routing module 410 typically includes at least one first connecting flange 431 and at least one second connecting flange 432. For example, the at least one first connecting flange 431 may be configured for connecting a process module as described herein. The at least one second connecting flange 432 may be configured for connecting a further routing module or a vacuum swing module. Typically, the routing module includes four connecting flanges, e.g. two first connecting flanges and two second connecting flanges, each pair of which being arranged on opposing sides of the routing module. Accordingly, the routing module may include three different types of connecting flanges, also referred to as routing flanges herein, e.g. a connecting flange for connecting a process module, a connecting flange for connecting a swing module, and a connecting flange for connecting a further routing module. Typically, some or all of the different types of connecting flanges have a casing frame-like structure which is configured for providing vacuum conditions inside the casing frame-like structure. Further, typically the connecting flanges may include an entrance/exit for the mask carrier and an entrance/exit for the substrate carrier.

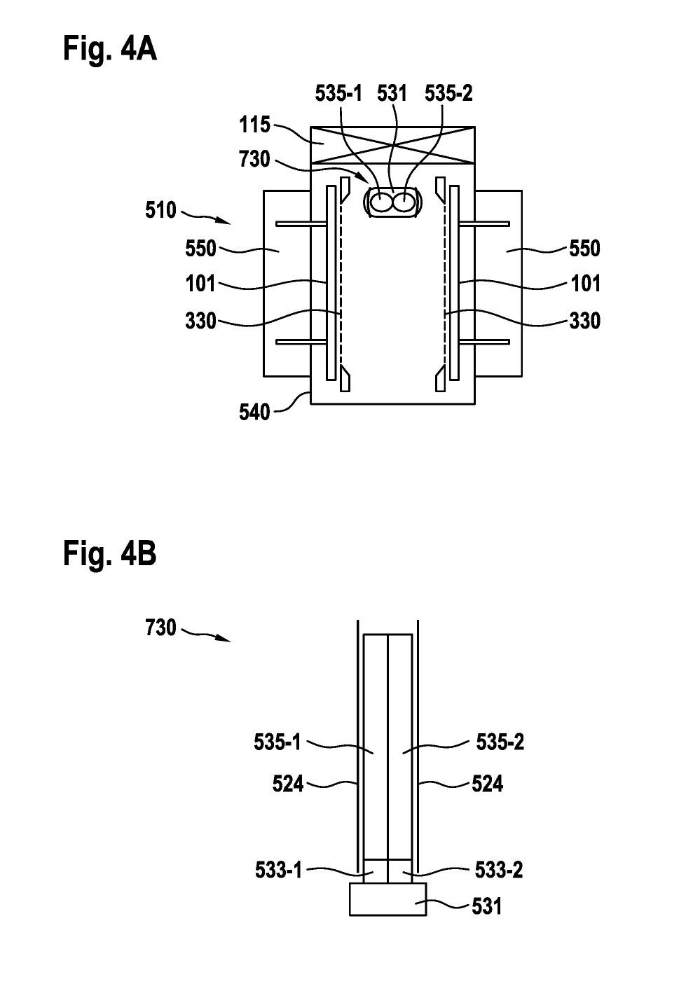

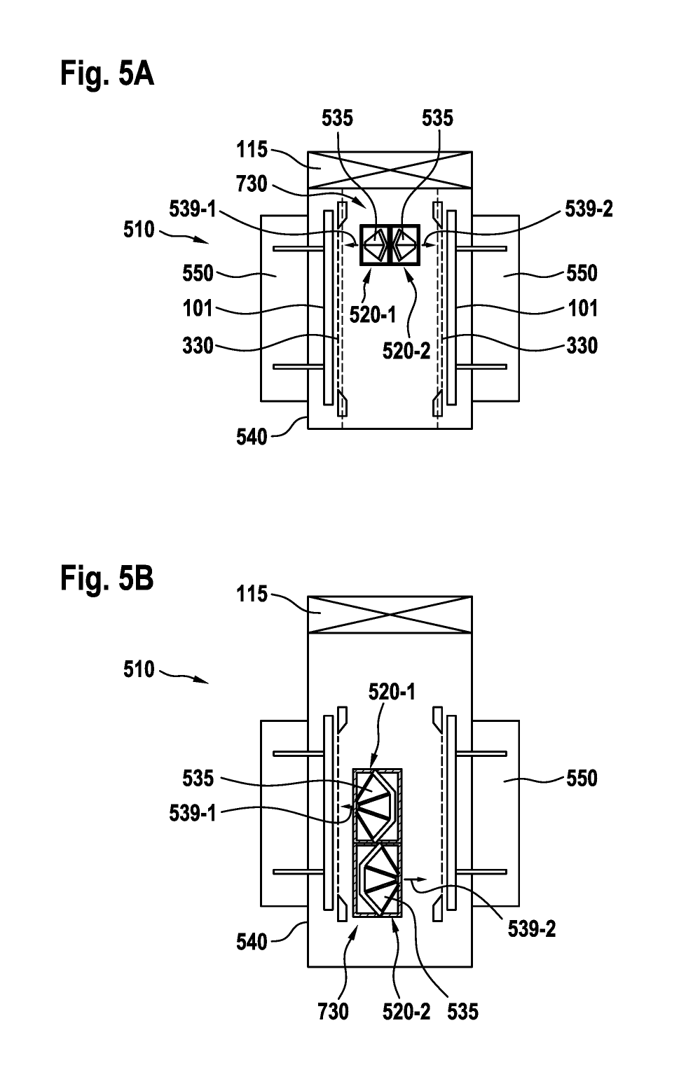

FIGS. 4A, 4B, 5A and 5B illustrate yet further process modules or deposition source assembly 730, respectively. According to such embodiments, which can be combined with other embodiments described herein, the deposition source assembly 730 includes a dual source or a first deposition source 520-1 and a second deposition source 520-2. As shown in FIGS. 4A and 4B, the first crucible 533-1 and the second crucible 533-2 are provided on the source support 531 of the deposition source assembly 730. The first crucible 533-1 is in fluid communication with the first distribution pipe 535-1. The second crucible 533-2 is in fluid communication with a second distribution pipe 535-2. Accordingly, a first deposition source and a second deposition source are provided independently from each other. For example, the first crucible and the second crucible can be two separate source material reservoirs with independent heating. This may be beneficial in order to maintain a sufficiently high vacuum difference (e.g. one order of magnitude or above) between the area inside the distribution pipe and outside the distribution pipe, e.g. in the vacuum process chamber.

According to some embodiments, which can be combined with other embodiments described herein, a first distribution pipe 535-1 ejects gaseous source material in a first direction indicated by arrow 539 and a second distribution pipe 535-2 deposits gaseous source material in the second direction indicated by arrow 539-2, wherein the second direction is opposite or essentially opposite to the first direction.

FIG. 5A shows an embodiment wherein the deposition source assembly includes two sources which are arranged back to back. Each of the two sources is configured for co-evaporation from the two distribution pipes. According to some embodiments, which can be combined with other embodiments described herein, also more than two distribution pipes can be provided for co-evaporation, for example for hosts and dopants of organic material forming a thin film of an OLED device. FIG. 5B shows an embodiment wherein the deposition source assembly includes two sources, which are arranged side by side. Each of the two sources is configured for co-evaporation from three distribution pipes.

According to some embodiments described herein, which can be combined with other embodiments described herein, a deposition source assembly may include three pairs of crucible systems with two sets of three linear sources (i.e. 6 linear sources) or may include three crucible systems with two sets of three linear sources (i.e. 6 linear sources). The crucible may evaporate the source materials constantly during operation of the deposition source assembly, i.e. the crucibles may be considered to be always switched “on”. A shutter to selectively open one set of linear sources for a first direction versus the other set of linear sources for the second direction essentially opposite to the first direction to sequentially deposit over two substrates can be provided.

According to some embodiments, which can be combined with other embodiments described herein, a first plurality of openings forming a first line source ejecting material in a first direction can be provided in the first distribution pipe of the distribution pipe assembly and the second plurality of openings forming a second line source ejecting material in an essentially opposite direction can be provided in a second distribution pipe. The first distribution pipe and the second distribution pipe may be supported by a common support and may be arranged back to back or side by side. According to some embodiments, which can be combined with other embodiments described herein, the exit(s) or openings of one source, for example deposition source 520-1, face away from the exit(s) of the other source, for example deposition source 520-2. The angle between the two ejection directions can be 120° to 100 a degrees.

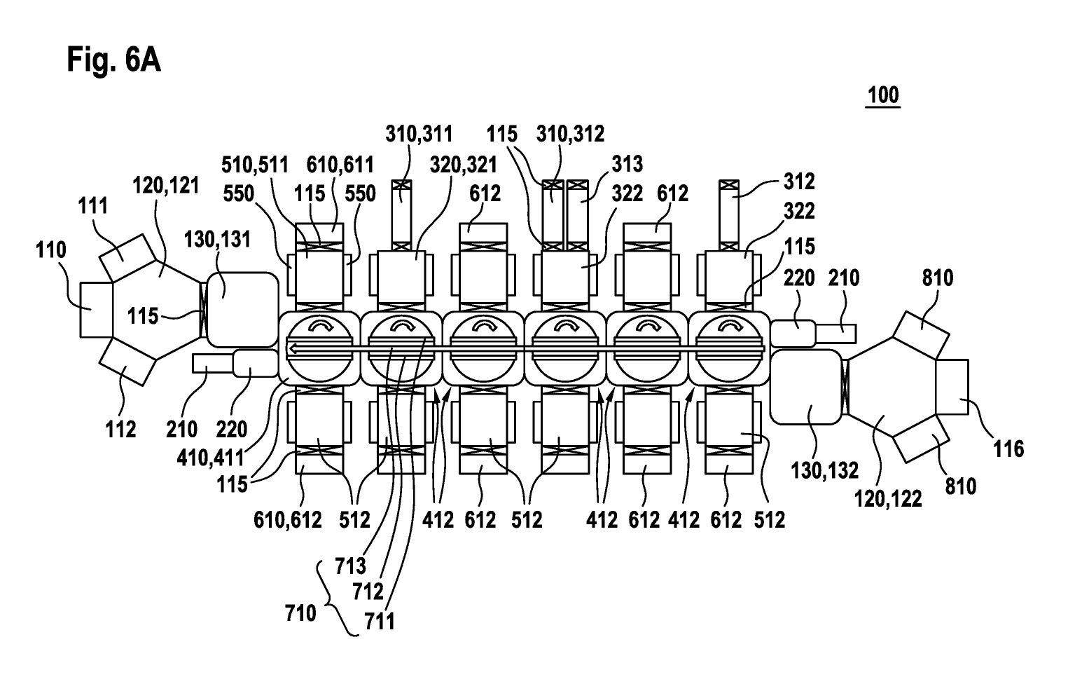

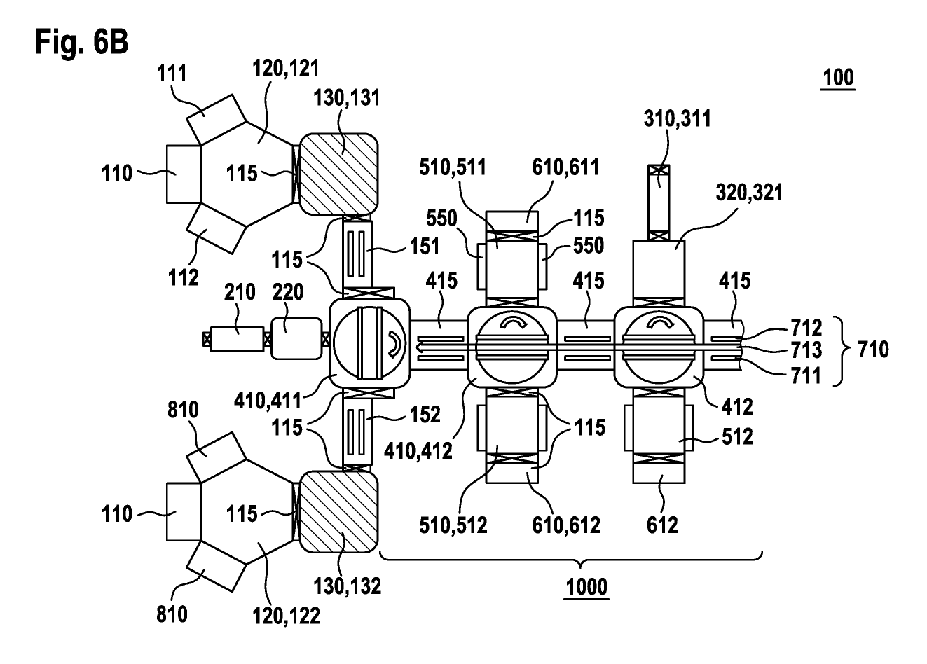

FIG. 6A shows a processing system 100 for manufacturing devices, particularly devices including organic materials therein. For example, the devices can be electronic devices or semiconductor devices, such as optoelectronic devices and particularly displays. In particular, the processing system as described herein is configured for improved carrier handling and/or mask handling during layer deposition on a substrate. These improvements can be beneficially utilized for OLED device manufacturing. However, the improvements in carrier handling and/or mask handling, which is provided by the concepts of arrangement of various system modules as described herein (also referred to as chambers), may also be utilized for other substrate processing systems, for example substrates processing systems including evaporation sources, sputter sources, particularly rotary sputter targets, CVD deposition sources, such as PECVD deposition sources, or combinations thereof. The embodiments of the present disclosure relate to manufacturing systems, particularly for processing large area substrates as described with respect to OLED manufacturing systems, as these OLED manufacturing systems may particularly benefit from the concepts described herein.

More specifically, the processing system 100 as described herein is configured for conducting an evaporation deposition method. The evaporation deposition method is based on the principle that a coating material evaporates in a vacuum controlled environment and condenses on a surface. A material deposition of a source material is conducted by at least one of evaporation and sublimation of the source material. In the following, reference is made to evaporation. Some materials that may be heated for evaporation may also be deposited by sublimation without referring explicitly to sublimation for the embodiments described herein.

To achieve a sufficient evaporation without reaching the boiling point of the evaporation material, the evaporation process is carried out in a vacuum environment. The principle of the evaporation deposition (or sublimation deposition) typically includes three phases: The first phase is the evaporating phase in which the material to be evaporated is heated in a crucible to an operating temperature. The operating temperature is set to create sufficient vapor pressure to move material from the crucible to the substrate. The second phase is the transport phase in which the vapor is moved from the crucible through, for example, a steam distribution pipe with nozzles onto a substrate for providing an even layer of the vapor onto the substrate. The third phase is the condensation phase in which the surface of the substrate has a lower temperature than the evaporated material which allows the vaporized material to adhere to the substrate.

With exemplary reference to FIG. 6A, according to embodiments which can be combined with other embodiments described herein, the processing system may include a vacuum swing module 130; a substrate carrier module 220; a routing module 410; a process module 510; a service module 610; a mask carrier loader 310; a mask carrier magazine 320; and a transportation system 710. Typically, a substrate carrier loader 210 in which the substrate carriers to be used are stored is connected to the substrate carrier module 220. Similarly, the mask carrier magazine 320 is configured to store masks which are intended to be used during processing of the substrate. According to some embodiments, the routing modules of the processing system may be connected directly to each other, as exemplarily shown in FIG. 6A. Alternatively, neighboring routing modules of the processing system may be connected via a transfer module 415, as exemplarily shown in FIG. 6B. In other words, typically a transfer module 415 including a vacuum transfer chamber may be installed between neighboring routing modules. Accordingly, typically the transfer module is configured to provide vacuum conditions inside the vacuum transfer chamber. Further, as schematically indicated in FIG. 6B, the transportation system 710, particularly a transportation apparatus for contactless levitation and transportation of a carrier assembly as described in more detail with reference to FIGS. 10A to 10B, can be provided in the transfer module 415. Further, the transfer module 415 may include a gate valve for a cryo-pump, a connecting flange for the cryo-pump and a connecting flange, also referred to as transfer flange herein, for connecting a routing module. Typically, the transfer flange includes a frame and sealing surface adapted to provide a vacuum-tight connection to a process module to be connected. According to some embodiments, the transfer module 415 may include an access door configured for providing access to the interior of the transfer module, e.g. for maintenance services.

With exemplary reference to FIGS. 6A and 6B, the processing system as described herein may be used for the production of display devices, particularly OLEDs. According to embodiments which can be combined with any other embodiment described herein, the processing system 100 is such that the processing of a substrate can be conducted under vacuum conditions. The substrate is loaded in the vacuum swing module 130, particularly the first vacuum swing module 131. The mask and substrate carrier loader stores all of the carriers (e.g. mask carriers and substrate carriers, respectively) that can be used in the processing system. The routing module 410 sends the mask and substrate carriers in the applicable process module. After processing, the substrate is unloaded from the processing system by a further vacuum swing module 132.

More specifically, with exemplary reference to FIG. 6A, according to some embodiments the processing system 100 may include a load lock chamber 110, which is connected to a first substrate handling chamber 121. The substrate can be transferred from the first substrate handling chamber 121 to the first vacuum swing module 131, wherein the substrate is loaded in a horizontal position on a carrier. After loading the substrate on the carrier in the horizontal position, the first vacuum swing module 131 rotates the carrier having the substrate provided thereon in a vertical or essentially vertical orientation. The carrier having the substrate provided thereon is then transferred through a first routing module 411 and a further routing module 412 for transferring the vertically orientated substrate to a process module 510. For example, in FIG. 6A six routing modules and ten process modules are shown.

With exemplary reference to FIG. 6A, according to embodiments which can be combined with any other embodiment described herein, a first pretreatment chamber 111 and a second pretreatment chamber 112 may be provided. Further, a robot (not shown) or another handling system can be provided in the substrate handling chamber 120. The robot or the another handling system can load the substrate from the load lock chamber 110 in the substrate handling chamber 120 and transfer the substrate into one or more of the pretreatment chambers. For example, the pretreatment chambers can include a pretreatment tool selected from the group consisting of: plasma pretreatment of the substrate, cleaning of the substrate, UV and/or ozone treatment of the substrate, ion source treatment of the substrate, RF or microwave plasma treatment of the substrate, and combinations thereof. After pretreatment of the substrates, the robot or another handling system may transfer the substrate out of the pretreatment chamber via the substrate handling chamber into the vacuum swing module 130.

In order to allow for venting the load lock chamber 110 for loading of the substrates and/or for handling of the substrate in the substrate handling chamber 120 under atmospheric conditions, at least one gate valve can be provided between the substrate handling chamber 120 and the vacuum swing module 130. Accordingly, the substrate handling chamber 120, and if desired one or more of the load lock chamber 110, the first pretreatment chamber 111 and the second pretreatment chamber 112, can be evacuated before the gate valve 115 is opened and the substrate is transferred into the first vacuum swing module 131. Accordingly, loading, treatment and processing of substrates may be conducted under atmospheric conditions before the substrate is loaded into the first vacuum swing module 131.

According to embodiments, typically the process module 510 can be connected to a routing module 410. For example, as exemplarily shown in FIG. 6A, a plurality of process modules (>8) may be provided, each being connected to one of the routing modules. Particularly, the process module 510 may be connected to a routing module 410, e.g. via a gate valve 115. A gate valve 115 as described herein may also be referred to as a lock valve. According to embodiments described herein, a gate valve or a lock valve can be used to separate the individual processing system modules (also referred to as processing system chambers) from each other. Accordingly, the processing system as described herein is configured such that the vacuum pressure in the individual processing system chambers can be controlled and changed separately and independently from each other.

According to some embodiments, and as shown in FIG. 6A, one or more routing modules (also referred to as rotation modules herein) are provided along a line for providing an in-line transportation system for transporting the substrate from one process module to another process module. Typically, as exemplarily shown in FIG. 6A, a transportation system 710 is provided in the processing system 100. The transportation system 710 is configured for transporting and transferring a substrate to be processed, typically supported by a carrier assembly, between the individual modules or chambers of the processing system 100. For instance, the transportation system 710 may include a first transportation track 711 and a second transportation track 712 along which carriers for supporting substrates or masks may be transported. In particular, the transportation system 710 may include at least one transportation apparatus for contactless levitation and transportation as described in more detail with reference to FIGS. 10A to 10B.

According to some embodiments, which can be combined with other embodiments described herein, the transportation system 710 may include a further track 713 provided within the two or more routing modules as exemplarily shown in FIG. 6A. In particular, the further track 713 may be a carrier return track.

With exemplary reference to FIG. 6A, according to embodiments which can be combined with any other embodiment described herein, an alignment system 550 can be provided at the process module 510, particularly at the vacuum process chamber 540. According to typical embodiments, a service module 610 (also referred to as maintenance module herein) can be connected to a process module 510, for example via a gate valve 115. Typically, the processing system includes two or more service modules, e.g. a first service module 611 and at least one second service module 612. As described herein, the service module allows for maintenance of deposition sources in the processing system.

With exemplary reference to FIGS. 6A and 6B, according to embodiments which can be combined with other embodiments described herein, the processing system 100 may include a mask carrier loader 310, e.g. a first mask carrier loader 311 and a second mask carrier loader 312, and a mask carrier magazine 320 for buffering various masks. In particular, the mask carrier magazine 320 may be configured to provide storage for replacement masks and/or masks which need to be stored for specific deposition processes. Accordingly, a mask employed in the processing system can be exchanged either for maintenance, such as cleaning, or for a variation of deposition pattern. Typically, the mask carrier magazine 320 may be connected to a routing module, e.g. to one of the further routing modules shown in FIG. 6A, for example via a gate valve 115. Accordingly, a mask can be exchanged without venting the vacuum process chamber and/or the routing module such that exposing the mask to atmospheric pressure can be avoided.

According to embodiments which can be combined with other embodiments described herein, a mask cleaning chamber 313 may be connected to the mask carrier magazine 320, e.g. via a gate valve 115, as exemplarily shown in FIG. 6A. For instance, a plasma cleaning tool can be provided in the mask cleaning chamber 313. Additionally or alternatively, a further gate valve 115 can be provided at the mask cleaning chamber 313, as shown in FIG. 6A, through which a cleaned mask may be unloaded from the processing system 100. Accordingly, a mask can be unloaded from the processing system 100 while only the mask cleaning chamber 313 needs to be vented. By unloading the mask from the manufacturing system, an external mask cleaning can be provided while the manufacturing system continues to be fully operating. FIG. 6A illustrates the mask cleaning chamber 313 adjacent to the mask carrier magazine 320. A corresponding or similar cleaning chamber (not shown) may also be provided adjacent to the substrate carrier module 220. By providing a cleaning chamber adjacent to the substrate carrier module 220, substrate carriers may be cleaned within the processing system.

After processing of the substrate, the substrate carrier having the substrate thereon is transferred from the last routing module into a further vacuum swing module 132 in the vertical orientation. The further vacuum swing module 132 is configured to rotate the carrier having the substrate thereon from the vertical orientation to a horizontal orientation. Thereafter, the substrate can be unloaded into a further horizontal substrate handling chamber. The processed substrate may be unloaded from the processing system 100 through a load lock chamber 110. Additionally or alternatively, the processed substrate can be encapsulated in a thin-film encapsulation chamber 810 which can be connected to the further vacuum swing module 132, as exemplarily shown in FIG. 6A. The one or more thin-film encapsulation chambers may include an encapsulation apparatus, wherein the deposited and/or processed layers, particularly an OLED material, are encapsulated between, i.e. sandwiched between, the processed substrate and a further substrate in order to protect the deposited and/or processed material from being exposed to ambient air and/or atmospheric conditions. However, other encapsulation methods like lamination with glass, polymer or metal sheets, or laser fusing of a cover glass may alternatively be applied by an encapsulation apparatus provided in one of the thin-film encapsulation chambers.

According to embodiments which can be combined with any other embodiment described herein, several mask carriers and substrate carriers can be moved through the processing system at the same time. Typically, the movement of the mask carriers and the substrate carriers is coordinated with the sequence tact times. The tact time may depend on the process and the module type.

Accordingly, a device such as an OLED display can be manufactured in the processing system 100 as exemplarily shown in FIGS. 6A and 6B as follows. The substrate can be loaded into the first substrate handling chamber 121 via a load lock chamber 110. A substrate pretreatment can be provided within the first pretreatment chamber 111 and/or the second pretreatment chamber 112 before the substrate is loaded in the first vacuum swing module 131. The substrate is loaded on a substrate carrier in the first vacuum swing module 131 and rotated from a horizontal orientation to a vertical orientation. Thereafter, the substrate is transferred through the first routing module 411 and one or more further routing modules. The routing modules are configured to rotate the substrate carrier with the substrate thereon such that the carrier with the substrate can be moved to a neighboring process module 510, as exemplarily indicated in FIG. 6A. For example, in the first process module 511, an electrode deposition can be conducted in order to deposit the anode of the device on the substrate. Thereafter, the carrier with the substrate can be removed from the first process module 511 and moved to one of the further process modules 512 which are connected to the routing modules. For example, one or more of the further process modules may be configured to deposit a hole injection layer, one or more of the further process modules may be configured to deposit a blue emission layer, a green emission layer or a red emission layer, one or more of the further process modules may be configured to deposit an electron transportation layer which is typically provided between the emission layers and/or above the emission layers. At the end of the manufacturing, a cathode can be deposited in one of the further process modules. Additionally, one or more exciton blocking layers (or hole blocking layers) or one or more electron injection layers may be deposited between the anode and the cathode in one of the further process modules. After deposition of all desired layers, the carrier is transferred to the further vacuum swing module 132, wherein the carrier with the substrate is rotated from the vertical orientation to a horizontal orientation. Thereafter, the substrate is unloaded from the carrier in the further substrate handling chamber 122 and can be transferred to one of the thin-film encapsulation chambers 810 for encapsulating the deposited layer stack. Thereafter, the substrate with the manufactured device can be unloaded from the processing system through an unload lock chamber 116.

With exemplary reference to FIG. 6B, according to embodiments which can be combined with other embodiments described herein, the processing system may be configured such that the loading and unloading of the substrate can be carried out on the same side of the processing system. In particular, with exemplary reference to FIG. 1B, according to some embodiments which can be combined with any other embodiments described herein, the processing system 100 for depositing one or more layers may include a first vacuum swing module 131, a first buffer chamber 151, a routing module 410, e.g. a first routing module 411, a second buffer chamber 152, a further vacuum swing module 132, and a processing arrangement 1000.

More specifically, with exemplary reference to FIG. 6B, the first vacuum swing module 131 is configured for rotating a first substrate 101A from a horizontal state into a vertical state. The first buffer chamber 151 is connected to the first vacuum swing module 131. The first buffer chamber 151 is configured for buffering the first substrate 101A received from the first vacuum swing module 131 in a first substrate transport direction. Further, the first buffer chamber 151 is configured for buffering a third substrate received from the routing module 410 in a second substrate transport direction 107. The routing module 410, particularly the first routing module 411, is connected to the first buffer chamber 151, and is configured for transporting the first substrate 101A to the processing arrangement 1000. The processing arrangement 1000 typically includes at least one deposition source as described herein. Further, the second buffer chamber 152 is connected to the routing module 410, particularly to the first routing module 411. The second buffer chamber 152 is configured for buffering a second substrate 101B received from the further vacuum swing module 132 in the second substrate transport direction. Further, the second buffer chamber 152 is configured for buffering a fourth substrate received from the routing module 410, particularly from the first routing module 411, in the first substrate transport direction. The further vacuum swing module 132 is connected to the second buffer chamber 152 and is configured for rotating the second substrate 101B from a vertical state into a horizontal state.

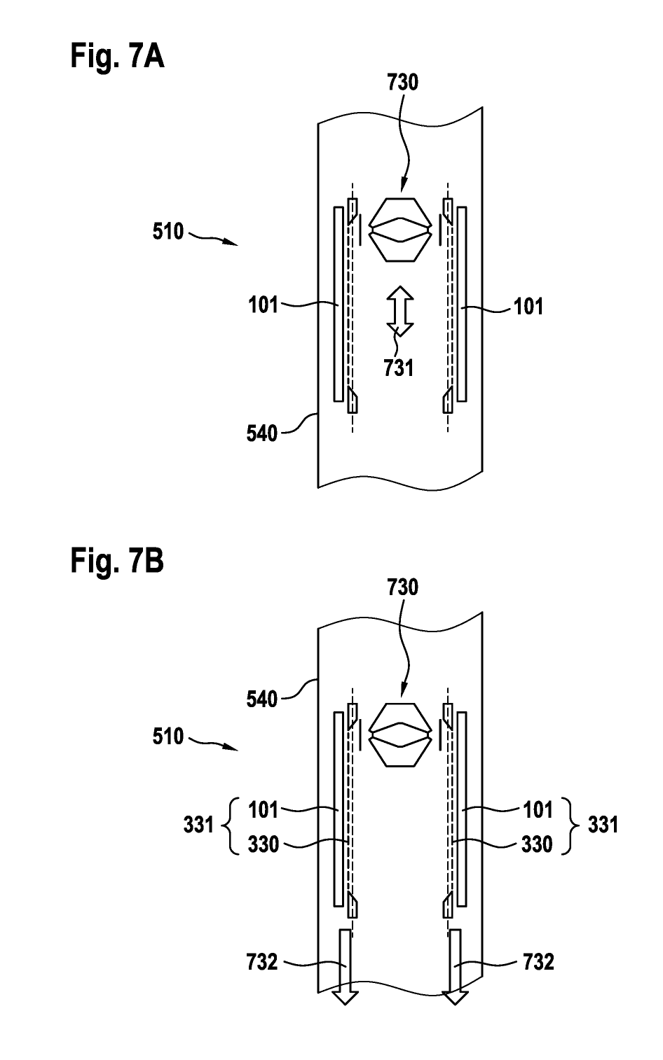

Further embodiments, which can be combined with other embodiments described herein, are explained with reference to FIGS. 7A and 7B. FIG. 7A shows a process module 510 wherein two substrates 101 are provided in a vacuum process chamber 540. A deposition source assembly 730, for example a deposition source assembly with three distribution pipes wherein each distribution pipe of the three distribution pipes ejects gaseous source material in a first direction and in an opposite second direction, is moved as indicated by arrow 731 in order to provide a relative movement between the deposition source assembly 730 and a substrate 101 on which the gaseous source material is to be deposited to form a thin film, for example a thin-film of an OLED device.

FIG. 7B shows a process module 510 wherein two substrates 101 are provided in a vacuum process chamber 540. Each of the substrates 101 is masked with a mask 330. The substrate 101 and the mask 330 provide a masked substrate arrangement. The masked substrate arrangement can for example be supported by a substrate carrier. The mask 330 shown in FIG. 7B can be a shadow mask for masking features to be deposited on the substrate. As indicated, the masked substrate arrangement moves past the deposition source assembly 730 to provide a relative movement between the deposition source assembly 730 and the substrate 101 on which the gaseous source material is to be deposited. According to yet further embodiments, which can be combined with other embodiments described herein, the mask substrate arrangement can for example be provided with an edge exclusion mask wherein only an outer rim portion, e.g. the outer edge of 0.2 mm to 5 mm, of the substrate is masked by the mask.

According to yet further embodiments, which can be combined with other embodiments described herein, a movement of the scanning source as shown in FIG. 7A and a movement of substrates as shown in FIG. 7B can be combined such that both the substrate and the source moves for deposition of the gaseous source material.

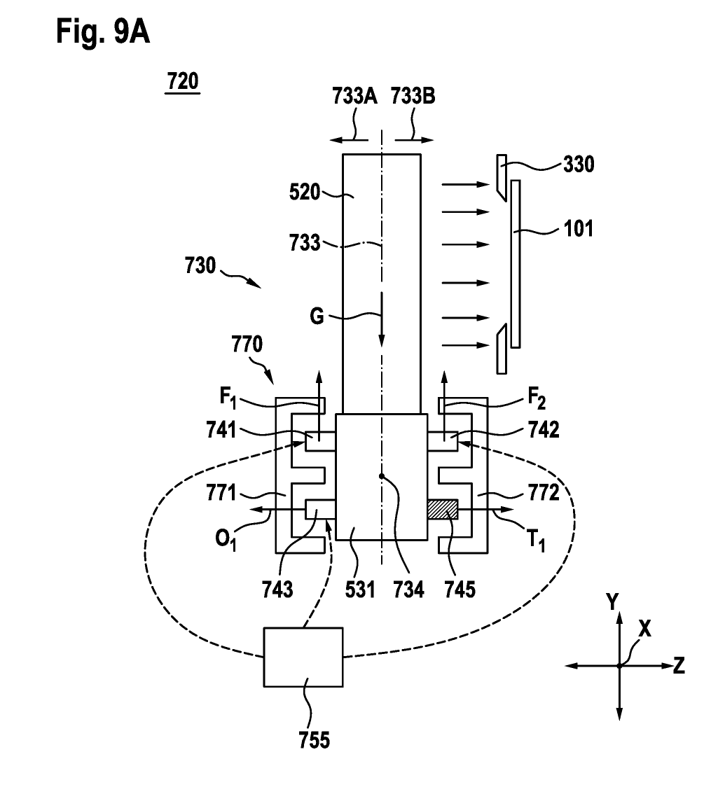

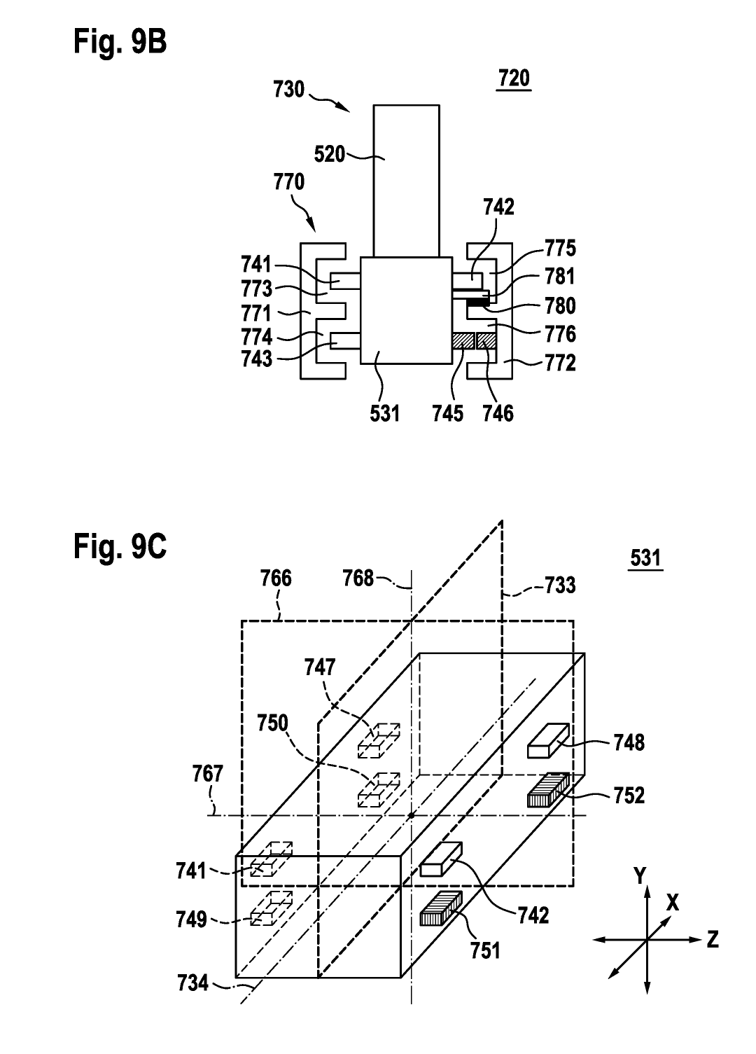

The movement of the deposition source assembly, for example a scanning source ejecting gaseous source material in a first direction and a second direction opposite to the first direction, is described in more detail with respect to FIGS. 9A to 9C. A movement of the substrate or a substrate carrier having a substrate mounted thereon is described in more detail with respect to FIGS. 10A and 10 B. A movement of a substrate or substrate carrier can be provided for loading or unloading of the substrate in a vacuum process chamber 540 and/or can be provided for moving a substrate past the deposition source ejecting gaseous source material in the first direction and a second direction opposite to the first direction.

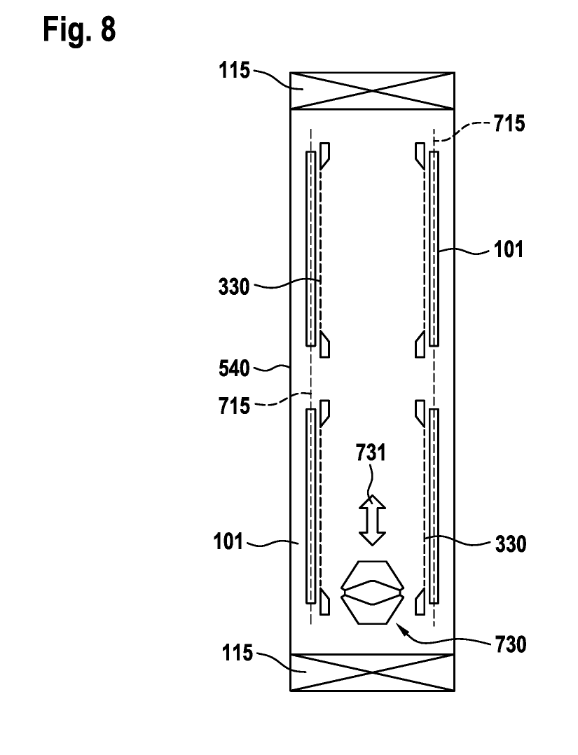

Embodiments shown above refer to a deposition source assembly having one or more movable shutters. FIG. 8 shows an embodiment of the vacuum process chamber 540, in which substrates 101 facing each other may be processed without a movable shutter for deposition source assembly 730. The vacuum process chamber 540 is connected to a first gate valve 115 and a second gate valve 115 at a side opposite to the first gate valve. Substrate 101 can be loaded and unloaded at opposing sides of the vacuum process chamber 540. In FIG. 8, these opposing sides are the upper side and the lower side of the vacuum process chamber 540.

The deposition source assembly 730 moves as indicated by arrow 731 and scans past the substrate 101. During movement, gaseous source material is ejected in a first direction and simultaneously in a second direction, which is opposite to the first direction. In FIG. 8, the first direction can exemplarily be the left side and the second direction can exemplarily be the right side. While thin films of the source material are deposited on two substrates facing each other at one end of the vacuum process chamber, two substrates at an opposing end of the vacuum process chamber can be exchanged. For example, previously processed substrates can be removed from the vacuum process chamber 540 and substrates to be processed can be inserted in the vacuum process chamber along a transportation track arrangement 715.

The deposition source assembly 730 continues the movement in order to deposit source material on the second pair of substrates facing each other. While the second pair of substrates, for example the upper pair in FIG. 8, is processed, the lower pair of substrates 101 can be removed from the vacuum process chamber 540 and a pair of substrates 101 to be processed thereafter can be inserted in the vacuum process chamber 540. Accordingly, gaseous source material is ejected simultaneously on both sides of the deposition source assembly while scanning along a pair of facing substrates. In light of the above, embodiments explained with respect to FIG. 8 and which can be combined with other embodiments described herein, may be provided without a movable shutter. This may beneficially increase the time interval between required servicing of a deposition source assembly.

According to embodiments described herein, a deposition source, for example a source for evaporation or sublimation of source material, is transported in a process chamber or a deposition system. Further, substrate carriers or substrates, respectively, and mask carriers or masks, respectively, are transported in a process chamber or a deposition system. In order to reduce particle generation, it is beneficial if one or more of the deposition sources, the substrates or substrate carriers, and the mask or mask carriers are transported with contactless levitation transportation, such as magnetic levitation transportation. The term “contactless” as used throughout the present disclosure can be understood in the sense that the weight of an element employed in the processing system, e.g. a deposition source assembly, a carrier or a substrate, is not held by a mechanical contact or mechanical forces, but is held by a magnetic force. Specifically, the deposition source assembly or the carrier assembly is held in a levitating or floating state using magnetic forces instead of mechanical forces. As an example, the transportation apparatuses described herein may have no mechanical element, such as a mechanical rail, supporting the weight of the deposition source assembly. In some implementations, there can be no mechanical contact between the deposition source assembly and the rest of the transportation apparatus at all during movement of the deposition source past the substrate.

With exemplary reference to FIGS. 9A-9C, a transportation apparatus 720 for contactless transportation of a deposition source assembly is described. Typically, the transportation apparatus 720 is arranged in a vacuum process chamber 540 of process module 510 as described herein. In particular, the transportation apparatus 720 is configured for contactless levitation, transportation and/or alignment of the deposition source. The contactless levitation, transportation and/or alignment of the deposition source is beneficial in that no particles are generated during transportation, for example due to mechanical contact with guide rails. Accordingly, embodiments of the transportation apparatus 720 described herein provide for an improved purity and uniformity of the layers deposited on the substrate, since particle generation is minimized when using the contactless levitation, transportation and/or alignment.

A further advantage, as compared to mechanical element for guiding the deposition source, is that embodiments described herein do not suffer from friction affecting the linearity of the movement of the deposition source along the substrate to be coated. The contactless transportation of the deposition source allows for a frictionless movement of the deposition source, wherein a target distance between the deposition source and the substrate can be controlled and maintained with high precision and speed. Further, the levitation allows for fast acceleration or deceleration of the deposition source speed and/or fine adjustment of the deposition source speed. Accordingly, the processing system as described herein provides for an improved layer uniformity, which is sensitive to several factors, such as e.g. variations in the distance between the deposition source and the substrate, or variations in the speed at which the deposition source is moved along the substrate while emitting material.

Further, the material of mechanical rails typically suffers from deformations which may be caused by evacuation of a chamber, by temperature, usage, wear, or the like. Such deformations affect the distance between the deposition source and the substrate, and hence affect the uniformity of the deposited layers. In contrast, embodiments of the transportation apparatus as described herein allow for a compensation of any potential deformations present, e.g. in the guiding structure. More specifically, the apparatus can be configured for a contactless translation of the deposition source assembly along a vertical direction, e.g. the y-direction, and/or along one or more transversal directions, e.g. the x-direction and z-direction, as described in more detail with reference to FIGS. 9A to 9C. An alignment range for the deposition source may be 2 mm or below, more particularly 1 mm or below.

In the present disclosure, the terminology of “substantially parallel” directions may include directions which make a small angle of up to 10 degrees with each other, or even up to 15 degrees. Further, the terminology of “substantially perpendicular” directions may include directions which make an angle of less than 90 degrees with each other, e.g. at least 80 degrees or at least 75 degrees. Similar considerations apply to the notions of substantially parallel or perpendicular axes, planes, areas or the like.

Some embodiments described herein involve the notion of a “vertical direction”. A vertical direction is considered to be a direction substantially parallel to the direction along which the force of gravity extends. A vertical direction may deviate from exact verticality (the latter being defined by the gravitational force) by an angle of, e.g., up to 15 degrees. For example, the y-direction described herein (indicated with “Y” in the figures) is a vertical direction. In particular, the y-direction shown in the figures defines the direction of gravity.

In particular, the transportation apparatus described herein can be used for vertical substrate processing. Therein, the substrate is vertically oriented during processing of the substrate, i.e. the substrate is arranged parallel to a vertical direction as described herein, i.e. allowing possible deviations from exact verticality. A small deviation from exact verticality of the substrate orientation can be provided, for example, because a substrate support with such a deviation might result in a more stable substrate position or a reduced particle adherence on a substrate surface. An essentially vertical substrate may have a deviation of +−15° or below from the vertical orientation.

As exemplarily illustrated in FIG. 9A, the transportation apparatus 720 typically includes a deposition source assembly 730 including a deposition source 520 as described herein and a source support 531 for supporting the deposition source 520. In particular, the source support 531 may be a source cart. The deposition source 520 may be mounted to the source support 531. As indicated by the arrows in FIG. 9A, the deposition source 520 is adapted for emitting material for depositing on the substrate 101. Further, as exemplarily shown in FIG. 9A, a mask 330 may be arranged between the substrate 101 and the deposition source 520. The mask 330 can be provided for preventing deposition of material emitted by the deposition source 520 on one or more regions of the substrate 101. For example, the mask 330 may be an edge exclusion shield configured for masking one or more edge regions of the substrate 101, such that no material is deposited on the one or more edge regions during the coating of the substrate 101. As another example, the mask may be a shadow mask for masking a plurality of features, which are deposited on the substrate with the material from the deposition source assembly.

Further, with exemplary reference to FIG. 9A, the deposition source assembly 730 may include a first active magnetic unit 741 and a second active magnetic unit 742. The transportation apparatus 720 typically further includes a guiding structure 770 extending in a deposition source transportation direction. The guiding structure 770 may have a linear shape extending along the source transport direction. The length of the guiding structure 770 along the source transportation direction may be from 1 m to 6 m. The first active magnetic unit 741, the second active magnetic unit 742 and the guiding structure 770 are configured for providing a first magnetic levitation force F1 and a first magnetic levitation force F2 for levitating the deposition source assembly 730, as exemplarily indicated in FIG. 9A.

In the present disclosure, an “active magnetic unit” or “active magnetic element”, may be a magnetic unit or magnetic element adapted for generating an adjustable magnetic field. The adjustable magnetic field may be dynamically adjustable during operation of the transportation apparatus. For example, the magnetic field may be adjustable during the emission of material by the deposition source 520 for deposition of the material on the substrate 101 and/or may be adjustable in between deposition cycles of a layer formation process. Alternatively or additionally, the magnetic field may be adjustable based on a position of the deposition source assembly 730 with respect to the guiding structure. The adjustable magnetic field may be a static or a dynamic magnetic field. According to embodiments, which can be combined with other embodiments described herein, an active magnetic unit or element can be configured for generating a magnetic field for providing a magnetic levitation force extending along a vertical direction. Alternatively, an active magnetic unit or element may be configured for providing a magnetic force extending along a transversal direction, e.g. an opposing magnetic force as described below. For instance, an active magnetic unit or active magnetic element as described herein may be or include an element selected from the group consisting of: an electromagnetic device; a solenoid; a coil; a superconducting magnet; or any combination thereof.

As exemplarily shown in FIG. 9A, during operation of the transportation apparatus 720, at least a portion of the guiding structure 770 may face the first active magnetic unit 741. The guiding structure 770 and/or the first active magnetic unit 741 may be arranged at least partially below the deposition source 520. The guiding structure 770 may be a static guiding structure which can be statically arranged in the vacuum process chamber. In particular, the guiding structure 770 may have magnetic properties. For example, the guiding structure 770 may be made of a magnetic material, e.g. a ferromagnetic, particularly ferromagnetic steel. Accordingly, the guiding structure may be or include a passive magnetic unit.

The terminology of a “passive magnetic unit” or “passive magnetic element” is used herein to distinguish from the notion of an “active” magnetic unit or element. A passive magnetic unit or element may refer to a unit or an element with magnetic properties which are not subject to active control or adjustment. For instance, a passive magnetic unit or element may be adapted for generating a magnetic field, e.g. a static magnetic field. A passive magnetic unit or element may not be configured for generating an adjustable magnetic field. Typically, a passive magnetic unit or element may be a permanent magnet or have permanent magnetic properties.

During a contactless movement of the deposition source assembly 730 along the guiding structure 770, the deposition source 520 may emit, e.g. continuously emit, material towards the substrate in the substrate receiving area for coating the substrate. The deposition source assembly 730 may sweep along the substrate such that, during one coating sweep, the substrate can be coated over the entire extent of the substrate along the source transportation direction. In a coating sweep, the deposition source assembly 730 may start from an initial position and move to a final position without changing direction.

According to embodiments, which can be combined with other embodiments described herein, the first active magnetic unit may be configured for generating a first adjustable magnetic field for providing a first magnetic levitation force F1. The second active magnetic unit may be configured for generating a second adjustable magnetic field for providing a second magnetic levitation force F2. The apparatus may include a controller 755 configured for individually controlling the first active magnetic unit 741 and/or the second active magnetic unit 742 for controlling the first adjustable magnetic field and/or the second adjustable magnetic field for aligning the deposition source. More specifically, the controller 755 may be configured for controlling the first active magnetic unit and the second active magnetic unit for translationally aligning the deposition source in a vertical direction. By controlling the first active magnetic unit and the second active magnetic unit, the deposition source assembly may be positioned into a target vertical position. Further, the deposition source assembly may be maintained in the target vertical position under the control of the controller.

The rotational degree of freedom provided by the individual controllability of the first active magnetic unit 741 and of the second active magnetic unit 742 allows controlling an angular orientation of the deposition source assembly 730 with respect to the first rotation axis 734. Under the control of the controller 755, a target angular orientation may be provided and/or maintained.

A further active magnetic unit 743 may be arranged at the first side 733A of the first plane 733. In operation, the further active magnetic unit 743 may face a first portion 771 of the guiding structure 770 and/or may be provided at least partially between the first plane 733 and the first portion 771. Typically, the first passive magnetic unit 745 and the guiding structure 770 are configured for providing a first transversal force T1.

In particular, the first passive magnetic unit 745 may be configured for generating a magnetic field. The magnetic field generated by the first passive magnetic unit 745 may interact with the magnetic properties of the guiding structure 770 to provide for the first transversal force T1 acting on the deposition source assembly 730. The first opposing force O1 may counteract the first transversal force T1 such that the net force acting on the deposition source assembly 730 along a transversal direction, e.g. the z-direction, is zero. Accordingly, the deposition source assembly 730 may be held without contact at a target position along a transversal direction.

As illustrated in FIG. 9A, the controller 755 may be configured for controlling the further active magnetic unit 743. The control of the further active magnetic unit 743 may include a control of an adjustable magnetic field generated by the further active magnetic unit 743 for controlling the first opposing transversal force O1. Controlling the further active magnetic unit 743 may allow for a contactless alignment of the deposition source 520 along a transversal direction, e.g. the z-direction.

With exemplary reference to FIG. 9B, according to some embodiments of transportation apparatus, a passive magnetic drive unit 780 may be provided at the guiding structure. For example, the passive magnetic drive unit 780 can be a plurality of permanent magnets, particularly a plurality of permanent magnets forming a passive magnet assembly with varying pole orientation. The plurality of magnets can have alternating pole orientation to form the passive magnet assembly. An active magnetic drive unit 781 can be provided at or in the source assembly, e.g. the source support 531. The passive magnetic drive unit 780 and the active magnetic drive unit 781 can provide the drive, e.g. a contactless drive, for movement along the guiding structure, while the source assembly is levitated.

FIG. 9C shows a source support 531, e.g. a source cart, according to embodiments which can be combined with other embodiments described herein. As shown, the following units may be mounted to the source support 531; the deposition source 520; a first active magnetic unit 741; a second active magnetic unit 742; a third active magnetic unit 747; a fourth active magnetic unit 748; a fifth active magnetic unit 749; a sixth active magnetic unit 750; a first passive magnetic unit 751; a second passive magnetic unit 752; or any combination thereof. The fifth active magnetic unit 749 may be a further active magnetic unit 743 as described with reference to FIG. 9A.

By controlling the first active magnetic unit, the second active magnetic unit, the third active magnetic unit and the fourth active magnetic unit, the deposition source may be translationally aligned along a vertical direction. Under the control of the controller, the deposition source may be positioned in a target position along a vertical direction, e.g. the y-direction.

By controlling, in particular individually controlling, the first active magnetic unit, the second active magnetic unit, the third active magnetic unit and the fourth active magnetic unit, the deposition source assembly may be rotated around the first rotation axis. Similarly, by controlling the units, the deposition source assembly may be rotated around the second rotation axis. The control of the active magnetic units allows controlling the angular orientation of the deposition source assembly with respect to the first rotation axis and the angular orientation with respect to the second rotation axis for aligning the deposition source. Accordingly, two rotational degrees of freedom for angularly aligning the deposition source can be provided.

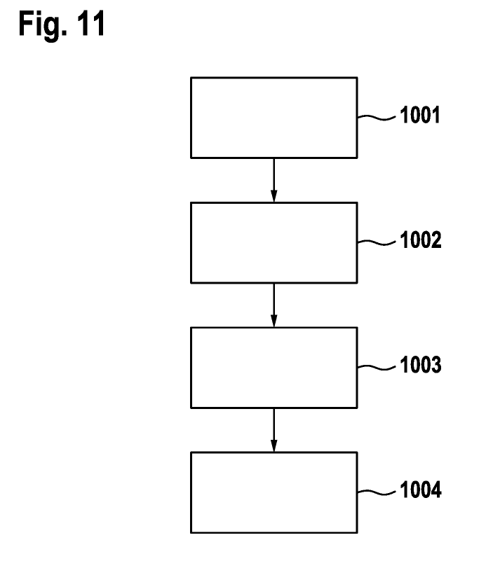

With exemplary reference to FIGS. 10A-11E, a further transportation apparatus 820 for contactless levitation, transportation and/or alignment of a carrier assembly or a substrate in a processing system as described herein is described. In the present disclosure, a “carrier assembly” may include one or more elements of the group consisting of: a carrier supporting a substrate, a carrier without a substrate, a substrate, or a substrate supported by a support. Specifically, the carrier assembly is held in a levitating or floating state using magnetic forces instead of mechanical forces. As an example, the further transportation apparatus described herein may have no mechanical element, such as a mechanical rail, supporting the weight of the deposition source assembly. In some implementations, there can be no mechanical contact between the carrier assembly and the rest of the further transportation apparatus at all during levitation, and for example movement, of the carrier assembly in the system.

The further transportation apparatus 820 is configured for a contactless translation of the carrier assembly along a vertical direction, e.g. the y-direction, and/or along one or more transversal directions, e.g. the x-direction. Further, the further transportation apparatus may be configured for a contactless rotation of the carrier assembly with respect to at least one rotation axis for angularly aligning the carrier assembly, e.g. relative to a mask.

FIG. 10A shows a front view of an exemplary further transportation apparatus 820 in the x-y-plane. Typically, the further transportation apparatus 820 may be arranged in the process module, particularly in the vacuum process chamber. Additionally, the further transport apparatus may also be provided in at least one further module of the processing system, e.g. in the transfer module 415 and/or the routing module 410 and/or the service module, and/or the mask carrier magazine 320 and/or the mask carrier loader 310 and/or the first buffer chamber 151 and/or the second buffer chamber and/or the first vacuum swing module 131 and/or further vacuum swing module 132.

As exemplarily shown in FIGS. 10A to 10B, the further transportation apparatus 820 may include a carrier assembly 880 which can include the substrate 101 to be transported, e.g. in a substrate carrier as described herein. The carrier assembly 880 typically includes a first passive magnetic element 851. As exemplarily shown in FIG. 10A, the further transportation apparatus may include a further guiding structure 870 extending in a carrier assembly transportation direction. The guiding structure includes a plurality of active magnetic elements 875. The carrier assembly 880 is configured to be movable along the further guiding structure 770, as exemplarily indicated with the horizontal arrow in FIG. 10A. The first passive magnetic element 851 and the plurality of active magnetic elements 875 of the further guiding structure 870 are configured for providing a first magnetic levitation force for levitating the carrier assembly 880.

Further, as exemplarily shown in FIG. 10A, the further transportation apparatus may include a drive structure 890. The drive structure can include a plurality of further active magnetic elements 895. The carrier assembly can include a second passive magnetic element 852, e.g. a bar of ferromagnetic material to interact with the further active magnetic elements 895 of the drive structure 890. Typically, an active magnetic element of the plurality of active magnetic elements 875 provides magnetic force interacting with the first passive magnetic element 851 of the carrier assembly 880. For example, the first passive magnetic element 851 can be a bar or a rod of a ferromagnetic material which can be a portion of the carrier assembly 880. Alternatively, first passive magnetic element may be integrally formed with a substrate support. Further, as exemplarily shown in FIGS. 10A and 10B, typically the carrier assembly 880 includes a second passive magnetic element 852, for example a further bar or further rod of ferromagnetic material, which can be connected to the carrier assembly 880 or be integrally formed with the substrate support.

According to embodiments described herein, the plurality of active magnetic elements 875 provides for a magnetic force on the first passive magnetic element 851 and, thus, on the carrier assembly 880. Accordingly, the plurality of active magnetic elements 875 levitate the carrier assembly 880. Typically, the further active magnetic elements 895 are configured to drive the carrier within the processing system along a substrate transport direction, for example along the X-direction shown in FIGS. 10A and 10B, i.e. along a first direction. Accordingly, the plurality of further active magnetic elements 895 form the drive structure for moving the carrier assembly 880 while being levitated by the plurality of active magnetic elements 875. The further active magnetic elements 895 interact with the second passive magnetic element 852 to provide a force along the substrate transport direction. For example, the second passive magnetic element 852 can include a plurality of permanent magnets, which are arranged with an alternating polarity. The resulting magnetic fields of the second passive magnetic element 852 can interact with the plurality of further active magnetic elements 895 to move the carrier assembly 880 while being levitated.

In order to levitate the carrier assembly 880 with the plurality of further active magnetic elements 895 and/or to move the carrier assembly 880 with the plurality of further active magnetic elements 895, the active magnetic elements can be controlled to provide adjustable magnetic fields. The adjustable magnetic field may be a static or a dynamic magnetic field. According to embodiments, which can be combined with other embodiments described herein, an active magnetic element is configured for generating a magnetic field for providing a magnetic levitation force extending along a vertical direction. According to other embodiments, which can be combined with further embodiments described herein, an active magnetic element may be configured for providing a magnetic force extending along a transversal direction. An active magnetic element, as described herein, may be or include an element selected from the group consisting of: an electromagnetic device; a solenoid; a coil; a superconducting magnet; or any combination thereof.

FIGS. 10A and 10B show side views of operational states of the further transportation apparatus 820 according to embodiments, which can be combined with other embodiments described herein. As shown, the further guiding structure 870 may extend along a transport direction of the carrier assembly, i.e. the X-direction in FIGS. 10A and 10B. The transport direction of the carrier assembly is a transversal direction as described herein. The further guiding structure 870 may have a linear shape extending along the transport direction. The length of the further guiding structure 870 along the source transportation direction may be from 1 to 30 m. The substrate 101 may be arranged substantially parallel to the drawing plane, e.g. with a deviation of +15°. The substrate may be provided in a substrate receiving area during the substrate processing, for example layer deposition process. The substrate receiving area has dimensions, e.g. a length and a width, which are the same or slightly (e.g. 5-20%) larger than the corresponding dimensions of the substrate.

During operation of the further transportation apparatus 820, the carrier assembly 880 may be translatable along the further guiding structure 870 in the transportation direction, e.g. the x-direction. FIGS. 10A and 10B show the carrier assembly 880 at different positions along the x-direction relative to the further guiding structure 870. The horizontal arrow indicates a driving force of the drive structure 890. As a result, a translation of the carrier assembly 880 from left to right along the further guiding structure 870 is provided. The vertical arrows indicate a levitation force acting on the carrier assembly.

The first passive magnetic element 851 may have magnetic properties substantially along the length of first passive magnetic element 851 in the transport direction. The magnetic field generated by the active magnetic elements 875′ interacts with the magnetic properties of the first passive magnetic element 851 to provide for a first magnetic levitation force and a second magnetic levitation force. Accordingly, a contactless levitation, transportation and alignment of the carrier assembly 880 may be provided.

As shown in FIG. 10A, the carrier assembly 880 is provided at a first position. According to embodiments of the present disclosure, two or more active magnetic elements 875′, for example two or three active magnetic elements 875, are activated by a carrier controller 840 to generate a magnetic field for levitating the carrier assembly 880. According to embodiments of the present disclosure, the carrier assembly hangs below the further guiding structure 870 without mechanical contact.

In FIG. 10A, two active magnetic elements 875′ provide a magnetic force, which is indicated by the vertical arrows. The magnetic forces counteract the gravity force in order to levitate the carrier assembly. The carrier controller 840 may individually control the two active magnetic elements 875′ to maintain the carrier assembly in a levitating state. Further, one or more further active magnetic elements 895′ can be controlled by the carrier controller 840. The further active magnetic elements interact with the second passive magnetic element 852, for example a set of alternating permanent magnets, to generate a driving force indicated by the horizontal arrow. The driving force moves the substrate, for example the substrate supported by the support of the carrier assembly, along the transport direction. As shown in FIG. 10A, the transport direction can be the X-direction. According to some embodiments of the present disclosure, which can be combined with other embodiments described herein, the number of further active magnetic elements 895′, which are simultaneously controlled to provide the driving force, is 1 to 3. The movement of the carrier assembly moves the substrate along the transport direction, for example the X-direction. Accordingly, at a first position, the substrate is positioned below the first group of active magnetic elements and at a further, different position, the substrate is positioned below the further, different group of active magnetic elements. The controller controls which active magnetic elements provides a levitation force for a respective position and controls the respective active magnetic elements to levitate the carrier assembly. For example, the levitating force can be provided by subsequent active magnetic elements' while the substrate is moving. According to embodiments described herein, the carrier assembly is handed over from one set of active magnetic elements to another set of active magnetic elements.

FIG. 10B shows the carrier assembly in a second position, e.g. a processing position, in which the substrate is processed in the process module. In the processing position, the carrier assembly can be moved to a desired position. The substrate is aligned relative to the mask with the contactless transport system described in the present disclosure.

In the second position, as exemplarily shown in FIG. 10B, two active magnetic elements 875′ provide a first magnetic force indicated by the left vertical arrow and a second magnetic force indicated by right vertical arrow. The carrier controller 840 controls the two active magnetic elements 875′ to provide for an alignment in a vertical direction, for example the Y-direction in FIG. 10B. Further, additionally or alternatively, the carrier controller 840 controls the two active magnetic elements 875′ to provide for an alignment, wherein the carrier assembly is rotated in the X-Y-plane. Both alignment movements can exemplarily be seen in FIG. 10B by comparing the position of the dotted carrier assembly and the position of the carrier assembly 880 drawn with solid lines.

The controller may be configured for controlling the active magnetic elements 875′ for translationally aligning the carrier assembly in a vertical direction. By controlling the active magnetic elements, the carrier assembly 880 may be positioned into a target vertical position. The carrier assembly 880 may be maintained in the target vertical position under the control of the carrier controller 840. Accordingly, the controller can be configured for controlling the active magnetic elements 875′ for angularly aligning the deposition source with respect to a first rotation axis, e.g. a rotational axis perpendicular to a main substrate surface, e.g. a rotational axis extending in a Z-direction in the present disclosure.

In some implementations, the carrier assembly 880 includes, or is, an electrodynamic chuck or Gecko chuck (G-chuck). The G-chuck can have a supporting surface for supporting the substrate thereon. The chucking force can be an electrodynamic force acting on the substrate to fix the substrate on the supporting surface.

FIG. 11 shows a flowchart illustrating methods of depositing evaporated source material on 2 or more substrates. According to some embodiments, as exemplarily illustrated in block 1001, a first substrate is moved in a vacuum process chamber. The first substrate and a deposition source assembly are moved relative to each other as illustrated by block 1002, wherein gaseous source material is ejected from the deposition source assembly at the first side of the deposition source assembly. For example the deposition source assembly scans along the first substrate for depositing a thin film, for example a thin film of organic material for manufacturing of an OLED device. For example, the thin film can include two or more organic materials such as hosts or dopants. As illustrated by block 1003, a second substrate is moved in the vacuum process chamber. For example, the first substrate can be moved along a first track of a transportation track arrangement and the second substrate can be moved along a second track of a transportation track arrangement. For depositing a thin film on the second substrate, the deposition source assembly and the second substrate are moved relative to each other while gaseous source material is ejected from the deposition source assembly on a second side of the deposition source assembly, which is opposite to the first side of the deposition source assembly, see block 1004.

A scanning of the deposition source assembly can be provided with a magnetic levitation as described with respect to FIGS. 9A to 9C. Switching between source material ejection on one side of the deposition source assembly and an opposing second side of the deposition source assembly can be provided by moving one or more movable shutters. Alternatively, as described with respect to FIG. 8, ejection of gaseous source material can be simultaneously provided on both sides of the deposition source assembly.

A plurality of embodiments, aspects and details are provided in the present disclosure, some of which are listed below as exemplary embodiments (EE(s)). EE1: A deposition source assembly for evaporating source material, including a body including a source material reservoir and a distribution pipe assembly for guiding gaseous source material in a first direction and a second direction opposite to the first direction. EE2: The deposition source assembly according to EE1, further including: one or more moveable shutters for selectively blocking propagation of the gaseous source material along at least one of the first direction and the second direction. EE3: The deposition source assembly according to EE2, wherein a first movable shutter of the one or more moveable shutters is configured to block gaseous source material guided in the first direction and a second movable shutter of the one or more moveable shutters is configured to block gaseous source material guided in the second direction. EE4: The deposition source assembly according to EE2, wherein the one or more moveable shutters are configured to be able to block gaseous source material guided in the first and the second direction. EE5: The deposition source assembly according to any of EEs 1 to 4, further comprising a heater to vaporize the source material into the gaseous source material. EE6: The deposition source assembly according to any of EEs 1 to 5, wherein an angle between the first direction and the second direction is between 120° and 180°. EE7: The deposition source assembly according to any of EEs 1 to 6, wherein the distribution pipe assembly includes a first plurality of openings forming a line source for guiding the gaseous source material in the first direction and a second plurality of openings forming a further line source for guiding the gaseous source materials in the second direction. EE8: The deposition source assembly according to claim EE7, wherein the first plurality of openings is provided in a distribution pipe of the distribution pipe assembly and the second plurality of openings is provided in the distribution pipe of the distribution pipe assembly. EE9: The deposition source assembly according to claim EE7, wherein the first plurality of openings is provided in a first distribution pipe of the distribution pipe assembly and the second plurality of openings is provided in a second distribution pipe of the distribution pipe assembly. EE10: The deposition source assembly according to EE 9, wherein first distribution pipe and the second distribution pipe are supported by a common source support. EE11: The deposition source assembly according to EE9 or EE10, wherein the first distribution pipe and the second distribution pipe are provided back to back or are provided side by side.

Further exemplary embodiments are provided for deposition apparatuses. EE12: A deposition apparatus for depositing evaporated source material on a substrate, including a vacuum chamber; a first substrate support track provided in the vacuum chamber, wherein the first substrate support track is configured to support a substrate in a first deposition area; a second substrate support track provided in the vacuum chamber, wherein the second substrate support track is configured to support a further substrate in a second deposition area, and wherein a space is provided between the first deposition area and the second deposition area; and a deposition source assembly for evaporating source material provided in the space between the first deposition area and the second deposition area, wherein the deposition source assembly comprises a body including a source material reservoir and a distribution pipe assembly for ejecting gaseous source material on a first side in a first direction and on a second side opposite to the first side in a second direction. EE13: The deposition apparatus according to EE12, wherein the deposition source assembly further comprises one or more moveable shutters for selectively blocking propagation of the gaseous source material along at least one of the first and the second direction. EE14: The deposition apparatus according to EE12 or EE13, wherein the distribution pipe assembly includes a first plurality of openings forming a line source for guiding the gaseous source material in the first direction and second plurality of openings forming a further line source for guiding the gaseous source materials in the second direction. EE15: The deposition apparatus according to any of EEs 12 to 14, wherein the first deposition area, the second deposition area and an length direction of the distribution pipe are parallel to a direction of gravity or have an angle relative to the direction of gravity of 20° or less, such as 15° or less. EE16: The deposition apparatus according to any of EEs 12 to 14, wherein the first deposition area, the second deposition area and an length direction of the distribution pipe are perpendicular to a direction of gravity or have an angle relative to the direction of gravity of 70° to 110°, such as 75° to 105°. EE17: The deposition apparatus according to EE14, wherein the deposition source assembly and a substrate transportation assembly are configured to provide a movement of the deposition source assembly and the substrate relative to each other along a translational direction such that the translation direction and a line source direction result in deposition of the gaseous source material on a substrate in one of the first deposition area and the second deposition area.

Further exemplary embodiments are provided methods of depositing evaporated source material. EE18: A method of depositing evaporated source material on two or more substrates, including moving a first substrate of the two or more substrates in a vacuum process chamber along a first substrate support track; moving the first substrate and a deposition source assembly relative to each other while ejecting gaseous source material at a first side of the deposition source assembly; moving a second substrate of the two or more substrates in the vacuum process chamber along a second substrate support track; and moving the second substrate and the deposition source assembly relative to each other while ejecting gaseous source material at a second side of the deposition source assembly opposite to the first side of the deposition source assembly. EE19: The method according to EE18, wherein moving the first substrate and the deposition source assembly relative to each other and wherein moving the second substrate and the deposition source assembly relative to each other is provided by a contactless movement of the deposition source between the first substrate support track and the second substrate support track. EE20: The method according to EE18 or EE19, wherein selectively ejecting the gaseous source material from the first side and the second side comprises moving of one or more movable shutters.

While the foregoing is directed to some embodiments, other and further embodiments may be devised without departing from the basic scope, and the scope is determined by the claims that follow.

1. A deposition source assembly for evaporating source material, comprising:
a body including a source material reservoir and a distribution pipe assembly for guiding gaseous source material in a first direction and a second direction opposite to the first direction.

2. The deposition source assembly according to claim 1, further comprising:
one or more moveable shutters for selectively blocking propagation of the gaseous source material along at least one of the first direction and the second direction.

3. The deposition source assembly according to claim 2, wherein a first movable shutter of the one or more moveable shutters is configured to block gaseous source material guided in the first direction and a second movable shutter of the one or more moveable shutters is configured to block gaseous source material guided in the second direction.

4. The deposition source assembly according to claim 2, wherein the one or more moveable shutters are configured to be able to block gaseous source material guided in the first and the second direction.

5. The deposition source assembly according to claim 1, further comprising a heater to vaporize the source material into the gaseous source material.

6. The deposition source assembly according to claim 1, wherein an angle between the first direction and the second direction is between 120° and 180°.

7. The deposition source assembly according to claim 1, wherein the distribution pipe assembly includes a first plurality of openings forming a line source for guiding the gaseous source material in the first direction and a second plurality of openings forming a further line source for guiding the gaseous source materials in the second direction.

8. The deposition source assembly according to claim 7, wherein the first plurality of openings is provided in a distribution pipe of the distribution pipe assembly and the second plurality of openings is provided in the distribution pipe of the distribution pipe assembly.

9. The deposition source assembly according to claim 7, wherein the first plurality of openings is provided in a first distribution pipe of the distribution pipe assembly and the second plurality of openings is provided in a second distribution pipe of the distribution pipe assembly.

10. The deposition source assembly according to claim 9, wherein first distribution pipe and the second distribution pipe are supported by a common source support.

11. The deposition source assembly according to claim 9, wherein the first distribution pipe and the second distribution pipe are provided back to back or are provided side by side.

12. A deposition apparatus for depositing evaporated source material on a substrate, comprising:
a vacuum chamber;
a first substrate support track provided in the vacuum chamber, wherein the first substrate support track is configured to support a substrate in a first deposition area;
a second substrate support track provided in the vacuum chamber, wherein the second substrate support track is configured to support a further substrate in a second deposition area, and wherein a space is provided between the first deposition area and the second deposition area; and
a deposition source assembly for evaporating source material provided in the space between the first deposition area and the second deposition area, wherein the deposition source assembly comprises a body including a source material reservoir and a distribution pipe assembly for ejecting gaseous source material on a first side in a first direction and on a second side opposite to the first side in a second direction.

13. The deposition apparatus according to claim 12, wherein the deposition source assembly further comprises one or more moveable shutters for selectively blocking propagation of the gaseous source material along at least one of the first and the second direction.

14. The deposition apparatus according to claim 12, wherein the distribution pipe assembly includes a first plurality of openings forming a line source for guiding the gaseous source material in the first direction and second plurality of openings forming a further line source for guiding the gaseous source materials in the second direction.

15. The deposition apparatus according to claim 12, wherein the first deposition area, the second deposition area and an length direction of the distribution pipe are parallel to a direction of gravity or have an angle relative to the direction of gravity of 20° or less, such as 15° or less.

16. The deposition apparatus according to claim 12, wherein the first deposition area, the second deposition area and an length direction of the distribution pipe are perpendicular to a direction of gravity or have an angle relative to the direction of gravity of 70° to 110°, such as 75° to 105°.

17. The deposition apparatus according to claim 14, wherein the deposition source assembly and a substrate transportation assembly are configured to provide a movement of the deposition source assembly and the substrate relative to each other along a translational direction such that the translation direction and a line source direction result in deposition of the gaseous source material on a substrate in one of the first deposition area and the second deposition area.

18. A method of depositing evaporated source material on two or more substrates, comprising:
moving a first substrate of the two or more substrates in a vacuum process chamber along a first substrate support track;
moving the first substrate and a deposition source assembly relative to each other while ejecting gaseous source material at a first side of the deposition source assembly;
moving a second substrate of the two or more substrates in the vacuum process chamber along a second substrate support track; and
moving the second substrate and the deposition source assembly relative to each other while ejecting gaseous source material at a second side of the deposition source assembly opposite to the first side of the deposition source assembly.

19. The method according to claim 18, wherein moving the first substrate and the deposition source assembly relative to each other and wherein moving the second substrate and the deposition source assembly relative to each other is provided by a contactless movement of the deposition source between the first substrate support track and the second substrate support track.

20. The method according to claim 18, wherein selectively ejecting the gaseous source material from the first side and the second side comprises moving of one or more movable shutters.
